(19) United States
(12) Patent Application Publication
(10) Pub. No.: US 2024/0427228 A1
(43) Pub. Date: Dec. 26, 2024

(54) PHOTOMASK BLANK, PHOTOMASK, AND MANUFACTURING METHOD OF PHOTOMASK

(71) Applicant: Kioxia Corporation, Tokyo (JP)

(72) Inventors: Kosuke TAKAI, Yokohama Kanagawa (JP); Katsuyoshi KODERA, Yokohama Kanagawa (JP)

(73) Assignee: Kioxia Corporation, Tokyo (JP)

(21) Appl. No.: 18/740,794

(22) Filed: Jun. 12, 2024

(30) Foreign Application Priority Data
Jun. 21, 2023 (JP) 2023-102059

(51) Int. Cl. G03F 1/26; G03F 1/48; G03F 1/80

(52) U.S. Cl. CPC G03F 1/26; G03F 1/48; G03F 1/80

(57) ABSTRACT

A photomask blank includes a substrate, a first transmittance adjusting film provided on the substrate, a phase shifter film provided on the first transmittance adjusting film, and a second transmittance adjusting film provided on the phase shifter film. When light having a wavelength transmits through the phase shifter film, a phase of the light transmitted through the phase shifter film and the first transmittance adjusting film is different from a phase of light passed through atmosphere with about 180 degrees, and a phase of the light transmitted through the phase shifter film and the second transmittance adjusting film is different from a phase of the light passed through the atmosphere with about 180 degrees.

### CROSS-REFERENCE TO RELATED APPLICATION

This application is based upon and claims the benefit of priority from Japanese Patent Application No. 2023-102059, filed Jun. 21, 2023, the entire contents of which are incorporated herein by reference.

### FIELD

Embodiments described herein relate generally to a photomask blank, a photomask, and a method for manufacturing the photomask.

### BACKGROUND

In a photomask for lithography, a transmittance of light in a film forming a photomask pattern may change in accordance with a region of the photomask. This change may result in issues when forming a photomask pattern.

### DESCRIPTION OF THE DRAWINGS

FIG. 1 is a cross-sectional view showing a structure of a photomask according to a first embodiment.

FIGS. 2A and 2B are cross-sectional views (1/7) showing a manufacturing method of the photomask according to the first embodiment.

FIGS. 3A and 3B are cross-sectional views (2/7) showing the manufacturing method of the photomask according to the first embodiment.

FIGS. 4A and 4B are cross-sectional views (3/7) showing the manufacturing method of the photomask according to the first embodiment.

FIGS. 5A and 5B are cross-sectional views (4/7) showing the manufacturing method of the photomask according to the first embodiment.

FIGS. 6A and 6B are cross-sectional views (5/7) showing the manufacturing method of the photomask according to the first embodiment.

FIGS. 7A and 7B are cross-sectional views (6/7) showing the manufacturing method of the photomask according to the first embodiment.

FIGS. 8A and 8B are cross-sectional views (7/7) showing the manufacturing method of the photomask according to the first embodiment.

FIG. 9 is a cross-sectional view showing a structure of a photomask according to a second embodiment.

FIGS. 10A and 10B are cross-sectional views (1/8) showing a manufacturing method of the photomask according to the second embodiment.

FIGS. 11A and 11B are cross-sectional views (2/8) showing the manufacturing method of the photomask according to the second embodiment.

FIGS. 12A and 12B are cross-sectional views (3/8) showing the manufacturing method of the photomask according to the second embodiment.

FIGS. 13A and 13B are cross-sectional views (4/8) showing the manufacturing method of the photomask according to the second embodiment.

FIGS. 14A and 14B are cross-sectional views (5/8) showing the manufacturing method of the photomask according to the second embodiment.

FIGS. 15A and 15B are cross-sectional views (6/8) showing the manufacturing method of the photomask according to the second embodiment.

FIGS. 16A and 16B are cross-sectional views (7/8) showing the manufacturing method of the photomask according to the second embodiment.

FIGS. 17A and 17B are cross-sectional views (8/8) showing the manufacturing method of the photomask according to the second embodiment.

FIG. 18 is a cross-sectional view showing a structure of a photomask according to a third embodiment.

FIGS. 19A and 19B are cross-sectional views (1/8) showing a manufacturing method of the photomask according to the third embodiment.

FIGS. 20A and 20B are cross-sectional views (2/8) showing the manufacturing method of the photomask according to the third embodiment.

FIGS. 21A and 21B are cross-sectional views (3/8) showing the manufacturing method of the photomask according to the third embodiment.

FIGS. 22A and 22B are cross-sectional views (4/8) showing the manufacturing method of the photomask according to the third embodiment.

FIGS. 23A and 23B are cross-sectional views (5/8) showing the manufacturing method of the photomask according to the third embodiment.

FIGS. 24A and 24B are cross-sectional views (6/8) showing the manufacturing method of the photomask according to the third embodiment.

FIGS. 25A and 25B are cross-sectional views (7/8) showing the manufacturing method of the photomask according to the third embodiment.

FIGS. 26A and 26B are cross-sectional views (8/8) showing the manufacturing method of the photomask according to the third embodiment.

FIGS. 27A and 27B are cross-sectional views (1/7) showing a manufacturing method of a photomask according to a fourth embodiment.

FIGS. 28A and 28B are cross-sectional views (2/7) showing the manufacturing method of the photomask according to the fourth embodiment.

FIGS. 29A and 29B are a cross-sectional view (3/7) showing the manufacturing method of the photomask according to the fourth embodiment.

FIGS. 30A and 30B are cross-sectional views (4/7) showing the manufacturing method of the photomask according to the fourth embodiment.

FIGS. 31A and 31B are cross-sectional views (5/7) showing the manufacturing method of the photomask according to the fourth embodiment.

FIGS. 32A and 32B are cross-sectional views (6/7) showing the manufacturing method of the photomask according to the fourth embodiment.

FIGS. 33A and 33B are cross-sectional views (7/7) showing the manufacturing method of the photomask according to the fourth embodiment.

### DETAILED DESCRIPTION

Embodiments provide a photomask blank, a photomask, and a manufacturing method of a photomask, in which a region dependence of a transmittance of light in a film forming a photomask pattern can be reduced.

In general, according to one embodiment, the photomask blank includes a substrate, a first transmittance adjusting film provided on the substrate, a phase shifter film provided on the first transmittance adjusting film, and a second transmittance adjusting film provided on the phase shifter film. When light having a wavelength transmits through the phase shifter film, a phase of the light transmitted through the phase shifter film and the first transmittance adjusting film is different from a phase of light passed through atmosphere with about 180 degrees, and a phase of the light transmitted through the phase shifter film and the second transmittance adjusting film is different from a phase of the light passed through the atmosphere with about 180 degrees.

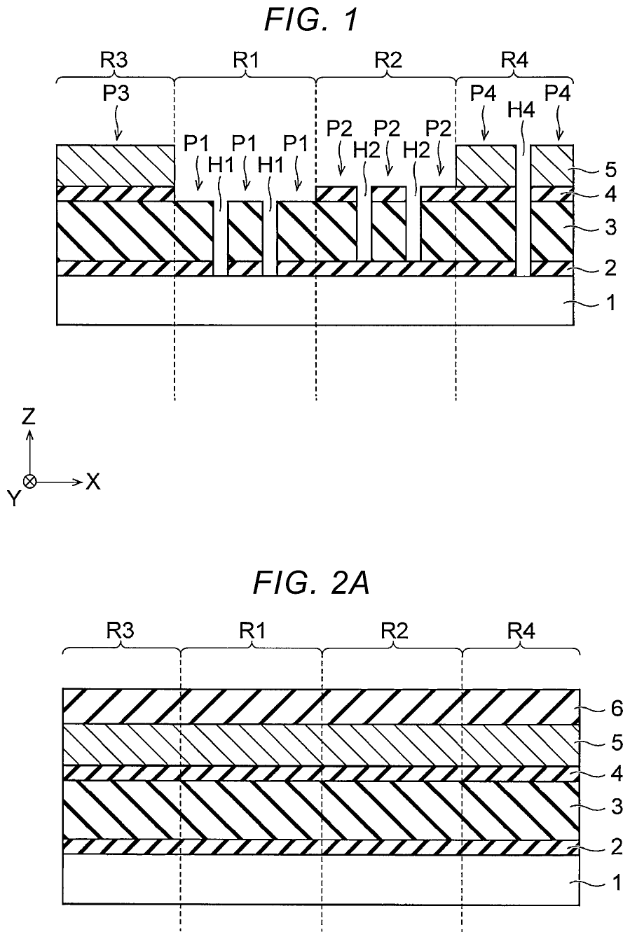

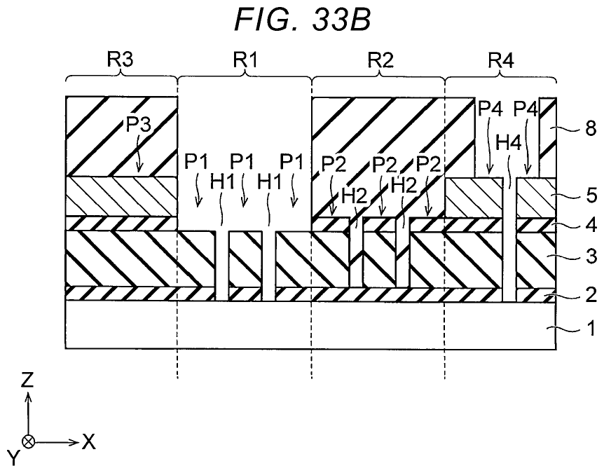

Hereinafter, embodiments of the present disclosure will be described with reference to the drawings. In FIGS. 1 to 33B, the same components are denoted by the same reference symbols, and redundant description will be omitted.

### First Embodiment

### 1) Photomask According to First Embodiment

FIG. 1 is a cross-sectional view showing a structure of a photomask according to a first embodiment.

The photomask according to the present embodiment includes a substrate 1, a transmittance adjusting film 2, an HT (halftone) film 3, a transmittance adjusting film 4, and a light shielding film 5. The transmittance adjusting film 2 is an example of a first transmittance adjusting film. The HT film 3 is an example of a phase shifter film. The transmittance adjusting film 4 is an example of a second transmittance adjusting film.

The substrate 1 is, for example, a transparent substrate such as a quartz substrate or a glass substrate. FIG. 1 shows X and Y directions parallel to a surface of the substrate 1 and perpendicular to each other, and a Z direction perpendicular to the surface of the substrate 1. The X direction, the Y direction, and the Z direction intersect each other. In the present specification, a +Z direction is regarded as an upward direction, and a −Z direction is regarded as a downward direction. The −Z direction may or may not coincide with a gravity direction.

The transmittance adjusting film 2 is formed on the substrate 1. The transmittance adjusting film 2 has an action of significantly changing (reducing) a transmittance of light of the photomask according to the present embodiment. In the present embodiment, the transmittance of light of the transmittance adjusting film 2 is lower than the transmittance of light of the HT film 3. The transmittance adjusting film 2 according to the present embodiment has a film thickness smaller than a film thickness of the HT film 3. The transmittance adjusting film 2 is, for example, an HfOₓ film (hafnium oxide film). The transmittance adjusting film 2 may be a film other than the HfOₓ film, and for example, may be an Hf film or an HAN film (hafnium nitride film), or may be a single metal film containing chromium (Cr), aluminum (Al), tungsten (W), tantalum (Ta), molybdenum (Mo), yttrium (Y), or Ruthenium (Ru), a metal oxide film, or a metal nitride film. In the present embodiment, the transmittance of light of the photomask is adjusted by the transmittance adjusting film 2.

The HT film 3 is formed on the transmittance adjusting film 2. The HT film 3 has an action of significantly changing the phase of light which transmits through the photomask according to the present embodiment. In the present embodiment, the amount of change in the phase of the light which transmits through the HT film 3 is larger than the amount of change in the phase of the light which transmits through the transmittance adjusting film 2 or the amount of change in the phase of the light which transmits through the transmittance adjusting film 4. The HT film 3 is, for example, a SiN film (silicon nitride film). The HT film 3 may contain Mo atoms together with Si atoms and N atoms. The transmittance of light of the HT film 3 is, for example, about 6% of the transmittance of light of the substrate 1. In the present embodiment, the phase of light which transmits through the photomask is shifted in the HT film 3.

The transmittance adjusting film 4 is formed on the HT film 3. The transmittance adjusting film 4, similar to the transmittance adjusting film 2, has the action of significantly changing (reducing) the transmittance of light of the photomask according to the present embodiment. In the present embodiment, the transmittance of light of the transmittance adjusting film 4 is lower than the transmittance of light of the HT film 3. The transmittance adjusting film 4 according to the present embodiment has a film thickness smaller than the film thickness of the HT film 3. The transmittance adjusting film 4 is, for example, an HfOₓ film. The transmittance adjusting film 4 may be a film other than the HfOₓ film, and for example, may be an Hf film or an HfN film, a single metal film containing Cr, Al, W, Ta, Mo, Y, or Ru, a metal oxide film, or a metal nitride film. In the present embodiment, the transmittance of light of the photomask is adjusted by the transmittance adjusting film 4.

The light shielding film 5 is formed on the transmittance adjusting film 4. The light shielding film 5 has an action of shielding light incident on the photomask according to the present embodiment. The light shielding film 5 is, for example, a Cr film.

The above-described transmittance is an energy transmittance representing a ratio of energy of light after being transmitted to energy of light before being transmitted. On the other hand, the amplitude transmittance represents a ratio of an amplitude of light after being transmitted to an amplitude of light before being transmitted. The energy transmittance is a square of the amplitude transmittance. In the present specification, the energy transmittance is simply referred to as “transmittance”.

As shown in FIG. 1, the photomask according to the present embodiment includes regions R1, R2, R3, and R4. The region R1 is an example of a first region. The region R2 is an example of a second region. The region R3 and the region R4 are examples of a third region.

The region R1 has a structure in which the substrate 1, the transmittance adjusting film 2, and the HT film 3 are provided, and the transmittance adjusting film 4 and the light shielding film 5 are not provided. Specifically, the region R1 includes a pattern portion P1 including the transmittance adjusting film 2 and the HT film 3, and a recess portion (non-pattern portion) H1 provided in the transmittance adjusting film 2 and the HT film 3. As described above, in the region R1, the transmittance adjusting film 2 and the HT film 3 form a photomask pattern. The recess portion H1 penetrates the HT film 3 and the transmittance adjusting film 2 and reaches the substrate 1. Therefore, the side surface of the recess portion H1 is formed of at least the HT film 3 and the transmittance adjusting film 2, and the bottom surface of the recess portion H1 is formed of the substrate 1. The recess portion H1 is an example of a first recess portion. Since the transmittance of light of the region R1 not including the transmittance adjusting film 4 is higher than the transmittance of light of the region R2 including the transmittance adjusting film 4, the region R1 is referred to as a bright region (bright mask).

The region R2 has a structure in which the substrate 1, the transmittance adjusting film 2, the HT film 3, and the transmittance adjusting film 4 are provided, and the light shielding film 5 is not provided. Specifically, the region R2 includes a pattern portion P2 including the HT film 3 and the transmittance adjusting film 4, and a recess portion (non-pattern portion) H2 provided in the HT film 3 and the transmittance adjusting film 4. As described above, in the region R2, the HT film 3 and the transmittance adjusting film 4 form a photomask pattern. The recess portion H2 penetrates the transmittance adjusting film 4 and the HT film 3 and reaches the transmittance adjusting film 2. Therefore, the side surface of the recess portion H2 is formed of at least the transmittance adjusting film 4 and the HT film 3, and the bottom surface of the recess portion H2 is formed of the transmittance adjusting film 2. The recess portion H2 is an example of a second recess portion. Since the transmittance of light of the region R2 including the transmittance adjusting film 4 is lower than the transmittance of light of the region R1 not including the transmittance adjusting film 4, the region R2 is referred to as a dark region (dark mask). For example, the amplitude transmittance of the dark region is about 70% of the amplitude transmittance of the bright region, and the transmittance (energy transmittance) of the dark region is about 49% of the transmittance of the bright region.

The region R3 has a structure including the substrate 1, the transmittance adjusting film 2, the HT film 3, the transmittance adjusting film 4, and the light shielding film 5. Similarly, the region R4 has a structure including the substrate 1, the transmittance adjusting film 2, the HT film 3, the transmittance adjusting film 4, and the light shielding film 5. The regions R3 and R4 form a light shielding frame of the photomask according to the present embodiment. As shown in FIG. 1, the region R3 includes a pattern portion P3 including the light shielding film 5, but does not include the recess portion. On the other hand, the region R4 includes a pattern portion P4 including the light shielding film 5 and a recess portion (non-pattern portion) H4 provided in the light shielding film 5, the transmittance adjusting film 4, the HT film 3, and the transmittance adjusting film 2. In the regions R3 and R4, the light shielding film 5 forms a light shielding pattern. The light shielding frame includes the region R4 in the present embodiment, but may not include the region R4. That is, the light shielding frame may or may not include the recess portion H4.

The transmittance adjusting film 2, the HT film 3, and the transmittance adjusting film 4 according to the present embodiment have predetermined properties with respect to light having a predetermined wavelength, for example, ArF excimer laser light (hereinafter, referred to as “ArF light”) (where Ar represents argon and F represents fluorine). A wavelength of the ArF excimer laser light is 193 nm.

Firstly, in the transmittance adjusting film 2 and the HT film 3 according to the present embodiment, a phase of the ArF light transmitted through the transmittance adjusting film 2 and the HT film 3 is different from a phase of the ArF light passed through the atmosphere by substantially 180 degrees. Therefore, the phase of the ArF light transmitted through the transmittance adjusting film 2 and the HT film 3 is a phase that is substantially inverted from the phase of the ArF light passed through the atmosphere. In this case, the phase of the ArF light transmitted through the pattern portion P1 of the region R1 is different from the phase of the ArF light passed through the recess portion H1 of the region R1 by substantially 180 degrees. The reason is that the pattern portion P1 includes the transmittance adjusting film 2 and the HT film 3, whereas the recess portion H1 does not include the transmittance adjusting film 2 and the HT film 3. The above-described “ArF light transmitted through the atmosphere” is here ArF light passed through the atmosphere at the same distance as the film thicknesses of the transmittance adjusting film 2 and the HT film 3.

Secondly, in the HT film 3 and the transmittance adjusting film 4 according to the present embodiment, the phase of the ArF light transmitted through the HT film 3 and the transmittance adjusting film 4 is different from the phase of the ArF light passed through the atmosphere by substantially 180 degrees. Therefore, the phase of the ArF light transmitted through the HT film 3 and the transmittance adjusting film 4 is a phase that is substantially inverted from the phase of the ArF light passed through the atmosphere. In this case, the phase of the ArF light transmitted through the pattern portion P2 of the region R2 is different from the phase of the ArF light passed through the recess portion H2 of the region R2 by substantially 180 degrees. The reason is that the pattern portion P2 includes the HT film 3 and the transmittance adjusting film 4, whereas the recess portion H2 does not include the HT film 3 and the transmittance adjusting film 4. The above-described “ArF light passed through the atmosphere” is here ArF light passed through the atmosphere at the same distance as the film thicknesses of the HT film 3 and the transmittance adjusting film 4.

As described above, the photomask according to the present embodiment includes the transmittance adjusting film 2 provided on the lower side of the HT film 3 and the transmittance adjusting film 4 provided on the upper side of the HT film 3. That is, the photomask according to the present embodiment includes the transmittance adjusting films 2 and 4 on both sides of the HT film 3, not on one side of the HT film 3. Hereinafter, the effects of the transmittance adjusting films 2 and 4 according to the present embodiment will be described.

In the present embodiment, the pattern portion P1 of the region R1 includes the HT film 3 and the transmittance adjusting film 2, and the pattern portion P2 of the region R2 includes the HT film 3 and the transmittance adjusting film 4. Therefore, there is a difference that the transmittance adjusting film 2 is formed on the lower side of the HT film 3 and the transmittance adjusting film 4 is formed on the upper side of the HT film 3, but both the pattern portion P1 and the pattern portion P2 include the HT film and the transmittance adjusting film. As a result, it is possible to bring the transmittance of the pattern portion P1 and the transmittance of the pattern portion P2 close to each other, and it is possible to bring the amount of change in the phase in the pattern portion P1 and the amount of change in the phase in the pattern portion P2 close to each other.

In addition, in the present embodiment, the region R1 includes the transmittance adjusting film 2 in the pattern portion P1, while the region R2 includes the transmittance adjusting film 2 under the pattern portion P2. As a result, it is possible to make the transmittance of the region R1 and the transmittance of the region R2 different from each other. Therefore, the region R1 is a bright mask, and the region R2 is a dark mask. According to the present embodiment, it is possible to make the optical characteristics of the regions R1 and R2 different while making the optical characteristics of the pattern portions P1 and P2 close to each other.

Here, it is assumed that the above-described photomask includes the transmittance adjusting film 4 but does not include the transmittance adjusting film 2. In this case, when the pattern portion P1 does not include the transmittance adjusting film 4 and the pattern portion P2 includes the transmittance adjusting film 4, it is possible to make the transmittance of the region R1 and the transmittance of the region R2 different from each other. Meanwhile, in this case, the pattern portions P1 and P2 also have different optical characteristics from each other. The reason is that the pattern portion P1 includes only the HT film 3, and the pattern portion P2 includes the HT film 3 and the transmittance adjusting film 4.

In addition, it is assumed that the above-described photomask includes the transmittance adjusting film 2 but does not include the transmittance adjusting film 4. In this case, when the recess portion H1 penetrates the transmittance adjusting film 2 and the recess portion H2 does not penetrate the transmittance adjusting film 2, it is possible to make the transmittance of the region R1 and the transmittance of the region R2 different from each other. Meanwhile, in this case, the pattern portions P1 and P2 also have different optical characteristics from each other. The reason is that the pattern portion P1 includes the transmittance adjusting film 2 and the HT film 3, and the pattern portion P2 includes only the HT film 3. The transmittance adjusting film 2 in the region R2 is located under the pattern portion P2, not in the pattern portion P2.

On the other hand, according to the present embodiment, since the above-described photomask includes both the transmittance adjusting films 2 and 4, it is possible to make the optical characteristics of the regions R1 and R2 different while making the optical characteristics of the pattern portions P1 and P2 close to each other. As a result, for example, it is possible to use both the region R1 and the region R2 as halftone masks, or to function the region R1 and the region R2 as halftone masks having different characteristics.

The photomask pattern according to the present embodiment is formed of the transmittance adjusting film 2 and the HT film 3 in the region R1, and is formed of the HT film 3 and the transmittance adjusting film 4 in the region R2. As a result, there is a difference that the transmittance adjusting film 2 is formed on the lower side of the HT film 3, and the transmittance adjusting film 4 is formed on the upper side of the HT film 3, but both the pattern portion P1 of the region R1 and the pattern portion P2 of the region R2 include the HT film and the transmittance adjusting film. Therefore, according to the present embodiment, it is possible to reduce the region dependence of the transmittance of light in the film forming the photomask pattern.

As described above, the photomask according to the present embodiment includes two regions R1 and R2 having different transmittances from each other as regions not including the light shielding film 5. On the other hand, the photomask according to the present embodiment may include three or more regions having different transmittances from each other as regions not including the light shielding film 5. For example, the photomask according to the present embodiment may include a region R1 having a high transmittance, a region R2 having a low transmittance, and another region having a moderate transmittance as a region not including the light shielding film 5.

### 2) Manufacturing Method of Photomask According to First Embodiment

FIGS. 2A to 8B are cross-sectional views showing a manufacturing method of the photomask according to the first embodiment.

First, a substrate 1 is prepared, and a transmittance adjusting film 2, an HT film 3, a transmittance adjusting film 4, a light shielding film 5, and a resist film 6 are sequentially formed on the substrate 1 (FIG. 2A). As a result, a photomask blank including the substrate 1, the transmittance adjusting film 2, the HT film 3, the transmittance adjusting film 4, the light shielding film 5, and the resist film 6 is manufactured. FIG. 2A shows regions R1 to R4 in the same manner as in FIG. 1.

In the present embodiment, a certain manufacturer may manufacture a photomask blank including the substrate 1, the transmittance adjusting film 2, the HT film 3, and the transmittance adjusting film 4, and another manufacturer may sequentially form the light shielding film 5 and the resist film 6 on the photomask blank. In addition, in the present embodiment, a certain manufacturer may manufacture a photomask blank including the substrate 1, the transmittance adjusting film 2, the HT film 3, the transmittance adjusting film 4, and the light shielding film 5, and another manufacturer may form the resist film 6 on the photomask blank.

Next, recess portions H1, H2, and H4 are formed in the resist film 6 of the regions R1, R2, and R4 by EB (electron beam) drawing and development, respectively (FIG. 2B).

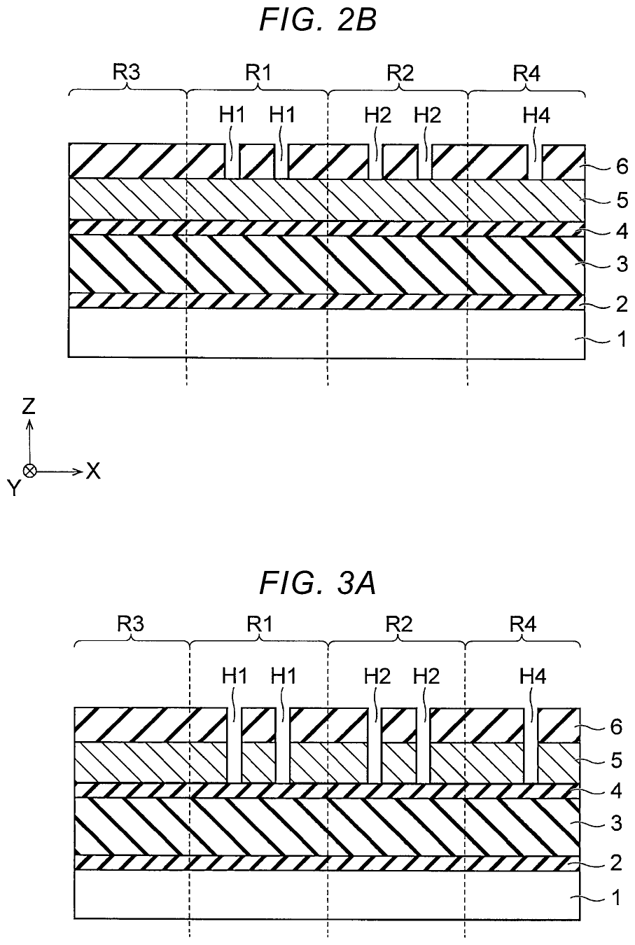

Next, the light shielding film 5 is processed by reactive ion etching (RIE) using the resist film 6 (FIG. 3A). As a result, the pattern of the resist film 6 is transferred to the light shielding film 5, and the recess portions H1, H2, and H4 are also formed in the light shielding film 5. The RIE in the step of FIG. 3A is performed using, for example, Cl₂ gas and O₂ gas (Cl represents chlorine).

Next, the transmittance adjusting film 4 is processed by RIE using the resist film 6 (FIG. 3B). As a result, the pattern of the resist film 6 is transferred to the transmittance adjusting film 4, and the recess portions H1, H2, and H4 are also formed in the transmittance adjusting film 4. The RIE in the step of FIG. 3B is performed using, for example, BCl₃ gas (B represents boron).

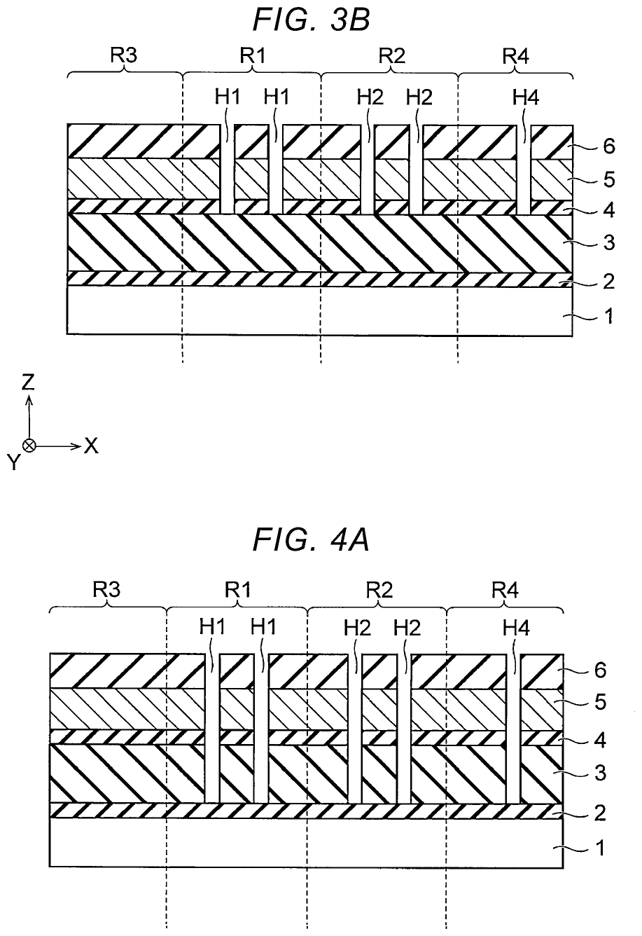

Next, the HT film 3 is processed by RIE using the resist film 6 (FIG. 4A). As a result, the pattern of the resist film 6 is transferred to the HT film 3, and the recess portions H1, H2, and H4 are also formed in the HT film 3. The RIE in the step of FIG. 4A is performed using, for example, SF₆ gas and Ar gas (S represents sulfur).

Next, the resist film 6 is peeled off (FIG. 4B). In this way, pattern portions P1, P2, P3, and P4 are formed in the regions R1, R2, R3, and R4, respectively. In FIG. 4B, the pattern portions P1 to P4 include the pattern of the light shielding film 5.

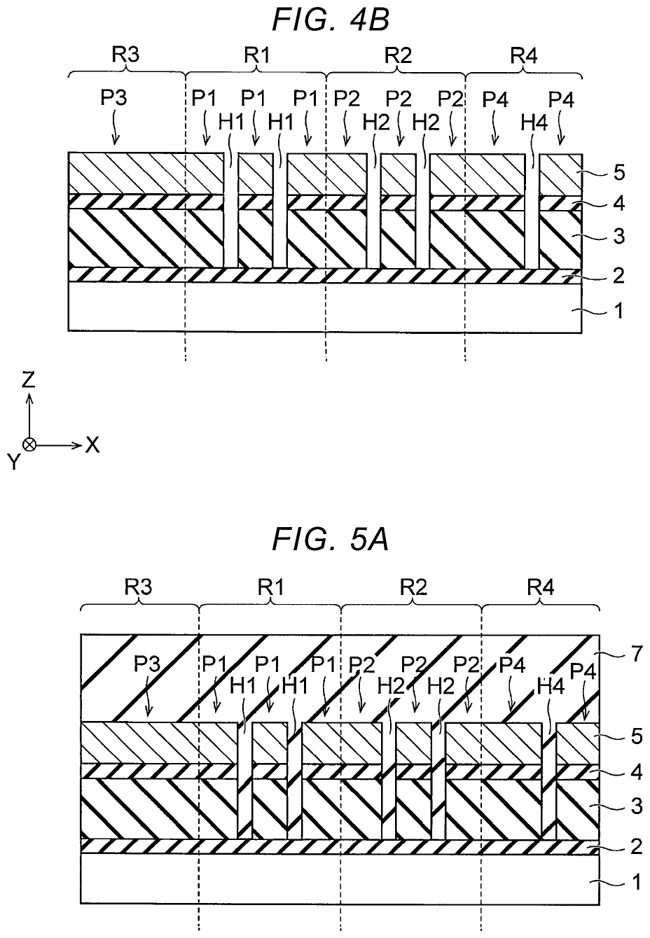

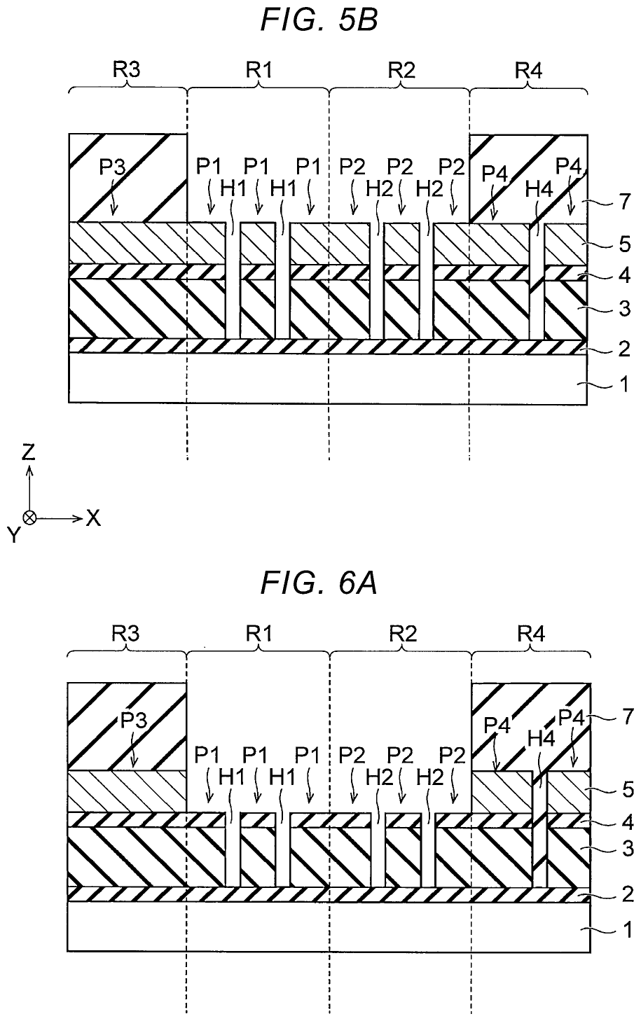

Next, a resist film 7 is formed on the light shielding film 5 (FIG. 5A). The resist film 7 is also formed in the recess portions H1, H2, and H4.

Next, the resist film 7 is removed from the regions R1 and R2 by laser drawing and development (FIG. 5B).

Next, the light shielding film 5 is processed by RIE using the resist film 7 (FIG. 6A). As a result, the pattern of the resist film 7 is transferred to the light shielding film 5, and the light shielding film 5 is removed from the regions R1 and R2. The RIE in the step of FIG. 6A is performed using, for example, Cl₂ gas and O₂ gas.

Next, the resist film 7 is peeled off (FIG. 6B). In FIG. 6B, the pattern portions P3 and P4 include the pattern of the light shielding film 5, and the pattern portions P1 and P2 include the patterns of the transmittance adjusting film 4 and the HT film 3.

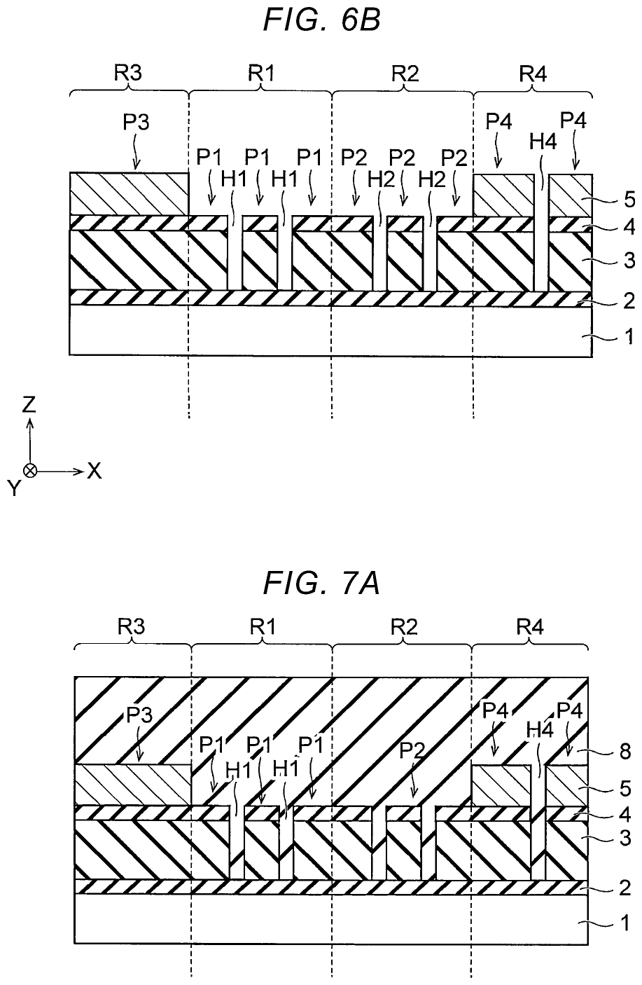

Next, a resist film 8 is formed on the light shielding film 5 and the transmittance adjusting film 4 (FIG. 7A). The resist film 8 is also formed in the recess portions H1, H2, and H4.

Next, the resist film 8 is removed from the entire region R1 and a part of the region R4 by laser drawing and development (FIG. 7B).

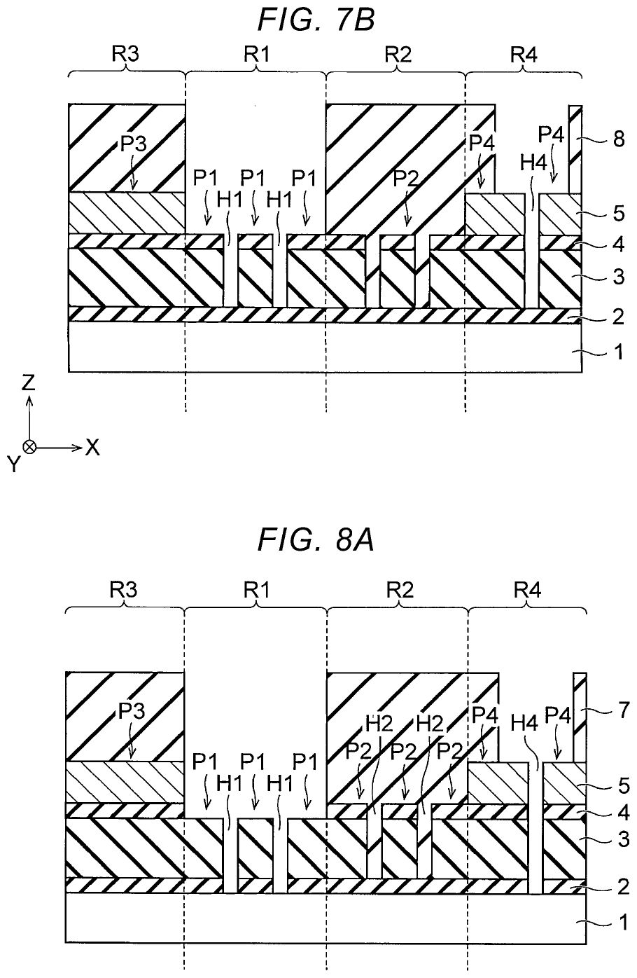

Next, the transmittance adjusting films 2 and 4 are simultaneously processed by RIE using the resist film 8 (FIG. 8A). As a result, the recess portions H1 and H4 are also formed in the transmittance adjusting film 2, and the transmittance adjusting film 4 is removed from the region R1. The RIE in the step of FIG. 8A is performed using, for example, BCl₃ gas. The light shielding film 5 exposed from the resist film 8 in the region R4 acts as a hard mask film during the RIE.

Next, the resist film 8 is peeled off (FIG. 8B). In FIG. 8B, the pattern portions P3 and P4 include the pattern of the light shielding film 5, the pattern portion P2 includes the patterns of the transmittance adjusting film 4 and the HT film 3, and the pattern portion P1 includes the patterns of the HT film 3 and the transmittance adjusting film 2.

In this way, the photomask shown in FIG. 1 is manufactured.

As described above, the photomask pattern according to the present embodiment is formed of the transmittance adjusting film 2 and the HT film 3 in the region R1, and is formed of the HT film 3 and the transmittance adjusting film 4 in the region R2. As a result, there is a difference that the transmittance adjusting film 2 is formed on the lower side of the HT film 3, and the transmittance adjusting film 4 is formed on the upper side of the HT film 3, but both the pattern portion P1 of the region R1 and the pattern portion P2 of the region R2 include the HT film and the transmittance adjusting film. Therefore, according to the present embodiment, it is possible to reduce the region dependence of the transmittance of light in the film forming the photomask pattern.

### Second Embodiment

### 1) Photomask According to Second Embodiment

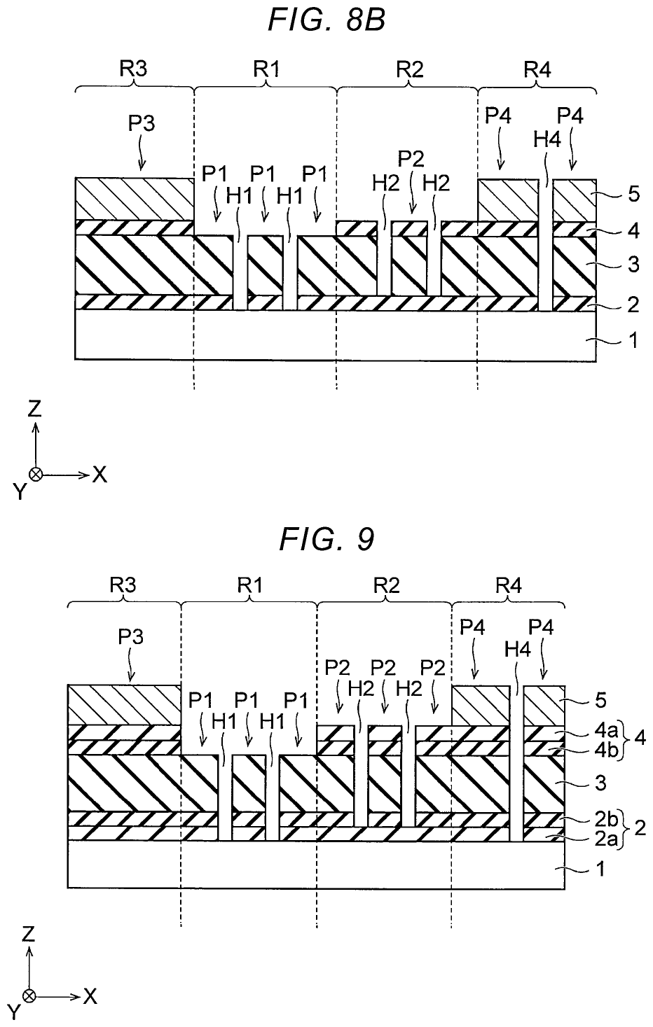

FIG. 9 is a cross-sectional view showing a structure of a photomask according to a second embodiment.

The photomask according to the present embodiment has the same structure as the photomask according to the first embodiment. Meanwhile, the transmittance adjusting film 2 according to the present embodiment includes transmittance adjusting films 2a and 2b. The transmittance adjusting film 2a is an example of a first film, and the transmittance adjusting film 2b is an example of a second film. Further, the transmittance adjusting film 4 according to the present embodiment includes transmittance adjusting films 4a and 4b. The transmittance adjusting film 4b is an example of a first film, and the transmittance adjusting film 4a is an example of a second film.

The transmittance adjusting film 2a is formed on a substrate 1. The transmittance adjusting film 2a is, for example, a SiN film. The transmittance adjusting film 2b is formed on the transmittance adjusting film 2a. The transmittance adjusting film 2b is, for example, an HfOₓ film. The transmittance adjusting film 2b may be a film other than the HfOₓ film, and for example, may be an Hf film or an HEN film, a single metal film containing Cr, Al, W, Ta, Mo, Y, or Ru, a metal oxide film, or a metal nitride film. In the present embodiment, the transmittance of light of the photomask is adjusted by the transmittance adjusting films 2a and 2b.

The transmittance adjusting film 4b is formed on an HT film 3. The transmittance adjusting film 4b is, for example, an HfOₓ film. The transmittance adjusting film 4b may be a film other than the HfOₓ film, and for example, may be an Hf film or an HEN film, a single metal film containing Cr, Al, W, Ta, Mo, Y, or Ru, a metal oxide film, or a metal nitride film. The transmittance adjusting film 4a is formed on the transmittance adjusting film 4b. The transmittance adjusting film 4a is, for example, a SiN film. In the present embodiment, the transmittance of light of the photomask is adjusted by the transmittance adjusting films 4a and 4b.

In addition, the regions R1 to R4 according to the present embodiment have the same characteristics as the regions R1 to R4 of the first embodiment. For example, in the transmittance adjusting film 2 and the HT film 3 according to the present embodiment, a phase of the ArF light transmitted through the transmittance adjusting film 2 and the HT film 3 is different from a phase of the ArF light passed through the atmosphere by substantially 180 degrees. In addition, in the HT film 3 and the transmittance adjusting film 4 according to the present embodiment, the phase of the ArF light transmitted through the HT film 3 and the transmittance adjusting film 4 is different from the phase of the ArF light passed through the atmosphere by substantially 180 degrees. Therefore, with the photomask according to the present embodiment, it is possible to obtain the same effects as those of the photomask according to the first embodiment.

### 2) Manufacturing Method of Photomask According to Second Embodiment

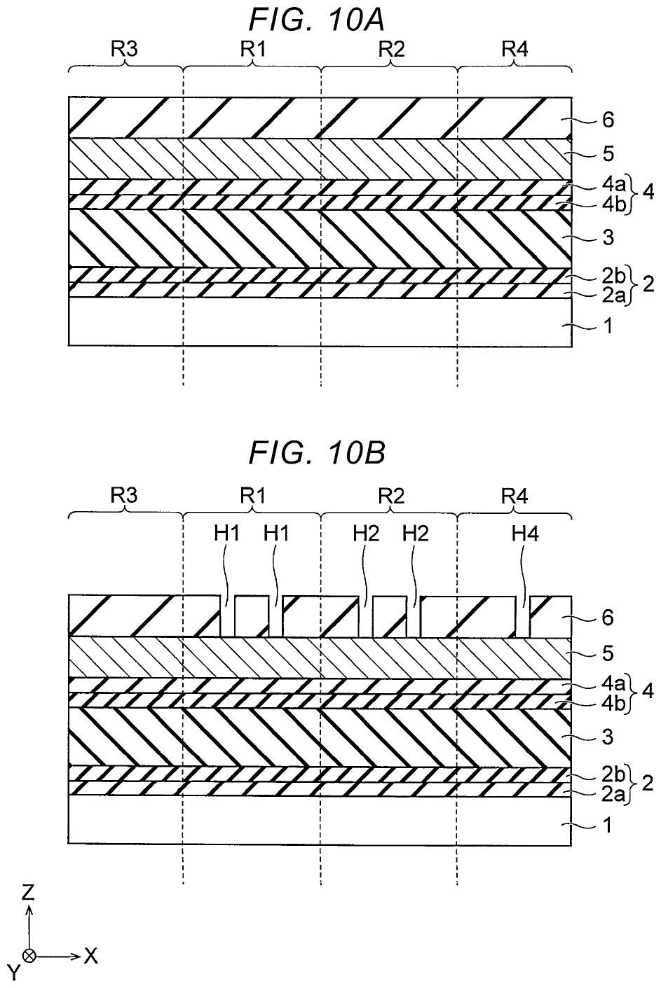

FIGS. 10A to 17B are cross-sectional views showing a manufacturing method of the photomask according to the second embodiment.

First, a substrate 1 is prepared, and a transmittance adjusting film 2, an HT film 3, a transmittance adjusting film 4, a light shielding film 5, and a resist film 6 are sequentially formed on the substrate 1 (FIG. 10A). As a result, a photomask blank including the substrate 1, the transmittance adjusting film 2, film the HT 3, the transmittance adjusting film 4, the light shielding film 5, and the resist film 6 is manufactured. FIG. 10A shows regions R1 to R4 in the same manner as in FIG. 9. The transmittance adjusting film 2 is formed by sequentially forming transmittance adjusting films 2a and 2b on the substrate 1. The transmittance adjusting film 4 is formed by sequentially forming transmittance adjusting films 4b and 4a on the HT film 3.

Next, recess portions H1, H2, and H4 are formed in the resist film 6 in the regions R1, R2, and R4 by EB drawing and the development, respectively (FIG. 10B).

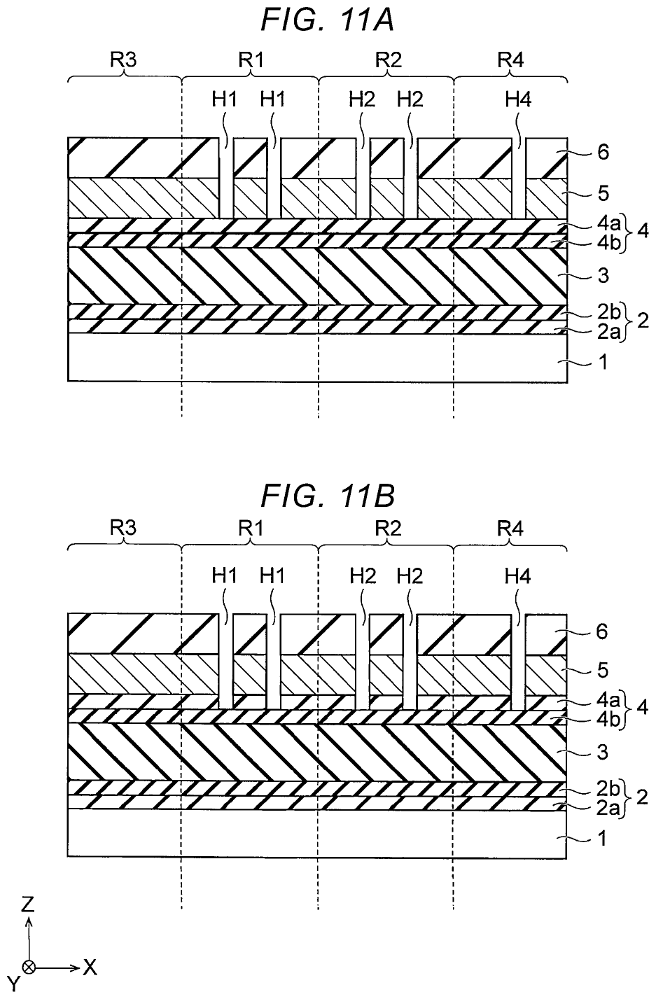

Next, the light shielding film 5 is processed by RIE using the resist film 6 (FIG. 11A). As a result, the recess portions H1, H2, and H4 are also formed in the light shielding film 5.

Next, the transmittance adjusting film 4a is processed by RIE using the resist film 6 (FIG. 11B). As a result, the recess portions H1, H2, and H4 are also formed in the transmittance adjusting film 4a. The RIE in the step of FIG. 11B is performed using, for example, SF₆ gas and Ar gas.

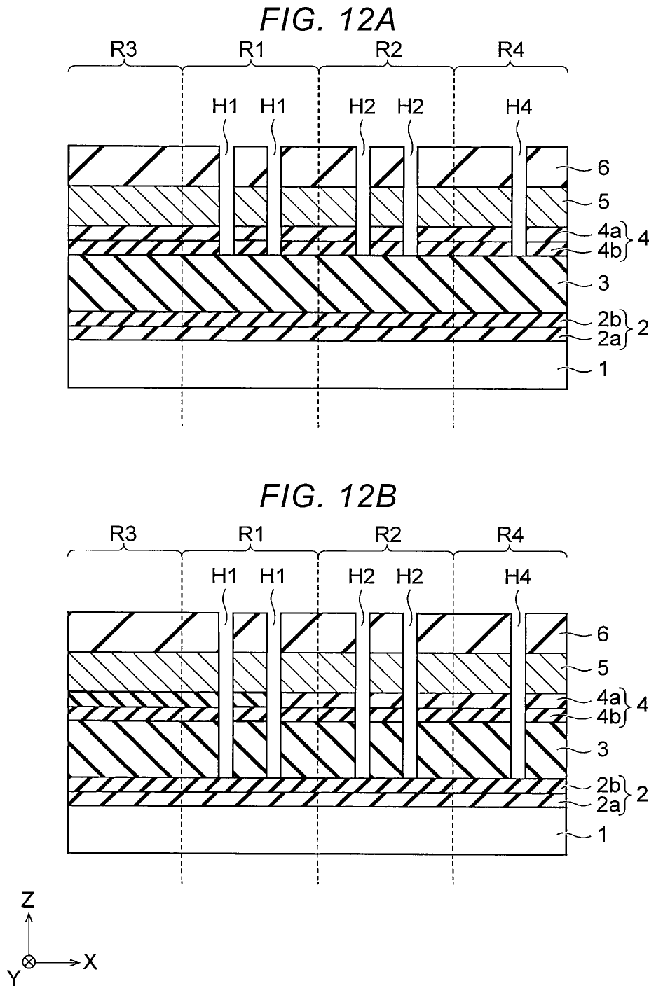

Next, the transmittance adjusting film 4b is processed by RIE using the resist film 6 (FIG. 12A). As a result, the recess portions H1, H2, and H4 are also formed in the transmittance adjusting film 4b. The RIE in the step of FIG. 12A is performed using, for example, BCl₃ gas.

Next, the HT film 3 is processed by RIE using the resist film 6 (FIG. 12B). As a result, the recess portions H1, H2, and H4 are also formed in the HT film 3.

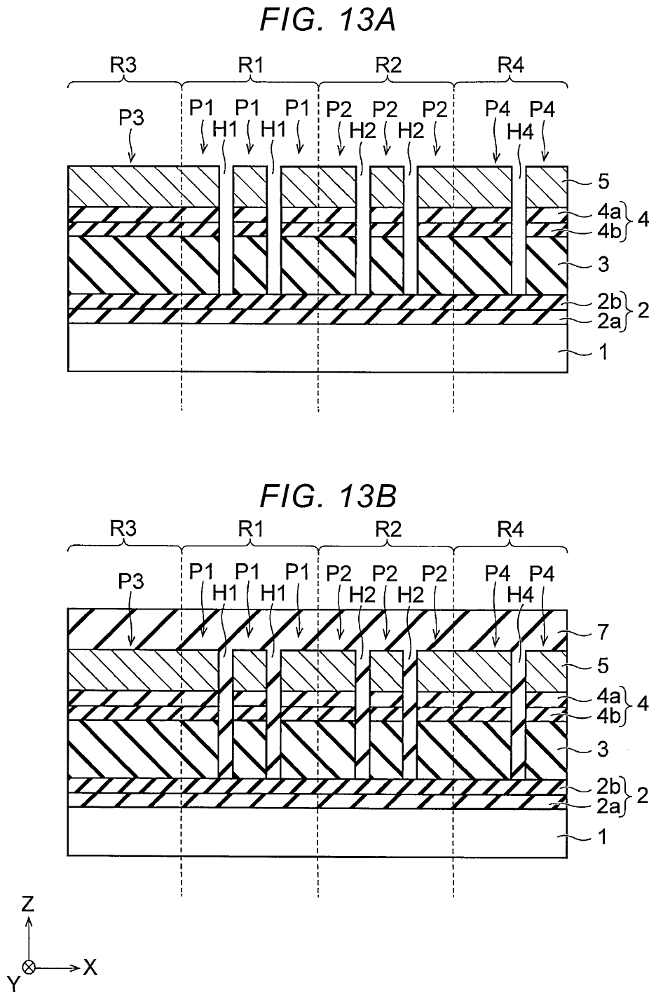

Next, the resist film 6 is peeled off (FIG. 13A). In this way, pattern portions P1, P2, P3, and P4 are formed in the regions R1, R2, R3, and R4, respectively.

Next, a resist film 7 is formed on the light shielding film 5 (FIG. 13B). The resist film 7 is also formed in the recess portions H1, H2, and H4.

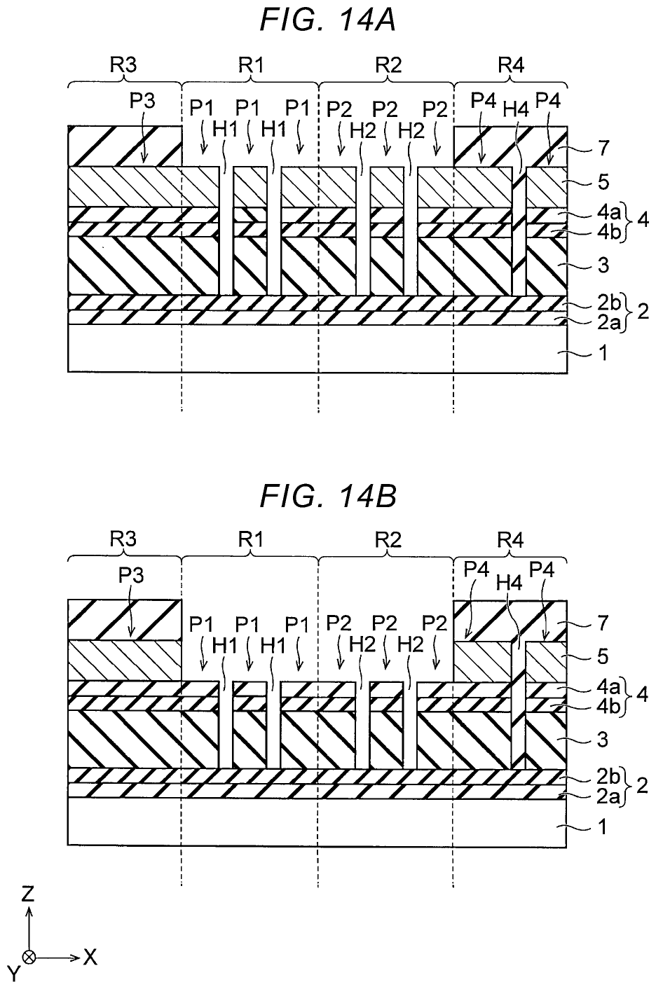

Next, the resist film 7 is removed from the regions R1 and R2 by laser drawing and development (FIG. 14A). Next, the light shielding film 5 is processed by RIE using the resist film 7 (FIG. 14B). As a result, the light shielding film 5 is removed from the regions R1 and R2.

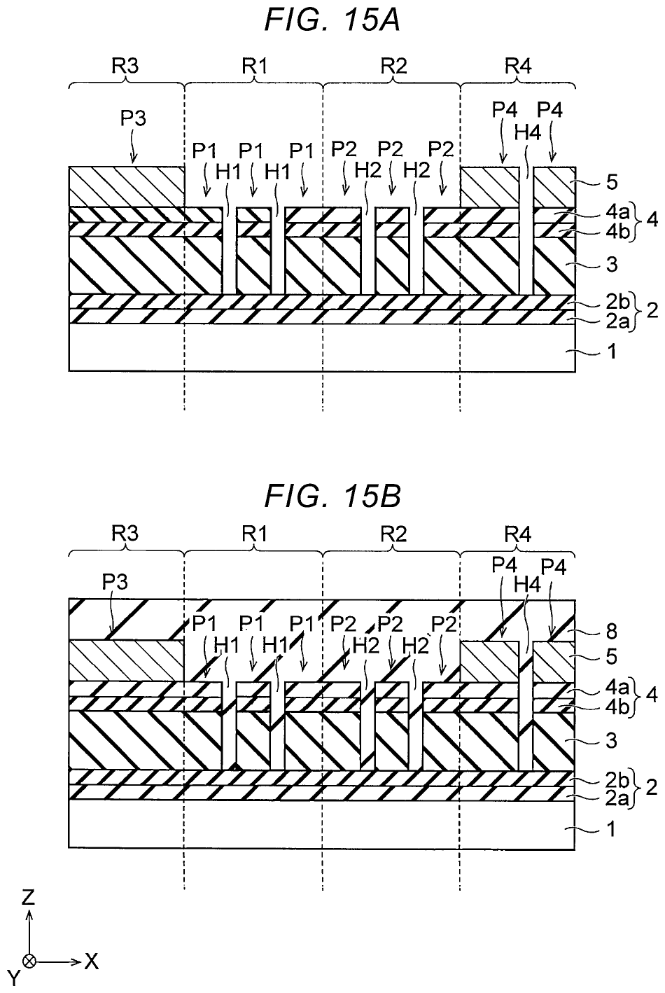

Next, the resist film 7 is peeled off (FIG. 15A). Next, a resist film 8 is formed on the light shielding film 5 and the transmittance adjusting film 4 (FIG. 15B). The resist film 8 is also formed in the recess portions H1, H2, and H4.

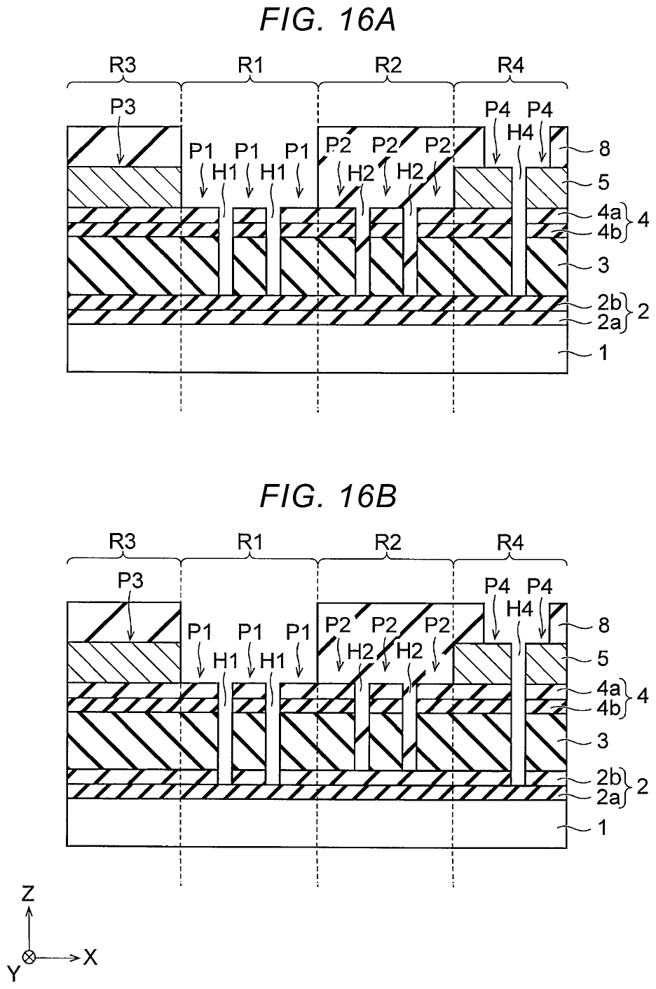

Next, the resist film 8 is removed from the entire region R1 and a part of the region R4 by laser drawing and development (FIG. 16A).

Next, the transmittance adjusting film 2b is processed by RIE using the resist film 8 (FIG. 16B). As a result, the recess portions H1 and H4 are also formed in the transmittance adjusting film 2b. The RIE in the step of FIG. 16B is performed using, for example, BCl₃ gas.

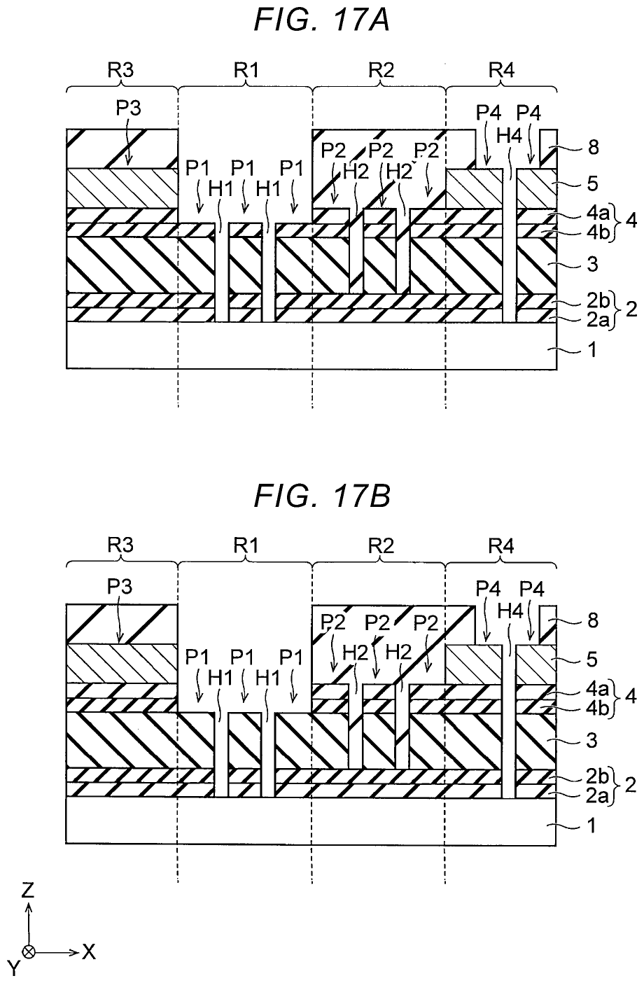

Next, the transmittance adjusting films 2a and 4a are simultaneously processed by RIE using the resist film 8 (FIG. 17A). As a result, the recess portions H1 and H4 are also formed in the transmittance adjusting film 2a, and the transmittance adjusting film 4a is removed from the region R1. The RIE in the step of FIG. 17A is performed using, for example, SF₆ gas and Ar gas.

Next, the transmittance adjusting film 4b is processed by RIE using the resist film 8 (FIG. 17B). As a result, the transmittance adjusting film 4b is removed from the region R1. The RIE in the step of FIG. 17B is performed using, for example, BCl₃ gas. Thereafter, the resist film 8 is peeled off.

In this way, the photomask shown in FIG. 9 is manufactured.

As described above, the photomask pattern according to the present embodiment is formed of the transmittance adjusting films 2a and 2b and the HT film 3 in the region R1, and is formed of the HT film 3 and the transmittance adjusting films 4a and 4b in the region R2. As a result, there is a difference that the transmittance adjusting films 2a and 2b are formed on the lower side of the HT film 3, and the transmittance adjusting films 4a and 4b are formed on the upper side of the HT film 3, but both the pattern portion P1 of the region R1 and the pattern portion P2 of the region R2 include the HT film and the transmittance adjusting film. Therefore, according to the present embodiment, it is possible to reduce the region dependence of the transmittance of light in the film forming the photomask pattern.

### Third Embodiment

### 1) Photomask According to Third Embodiment

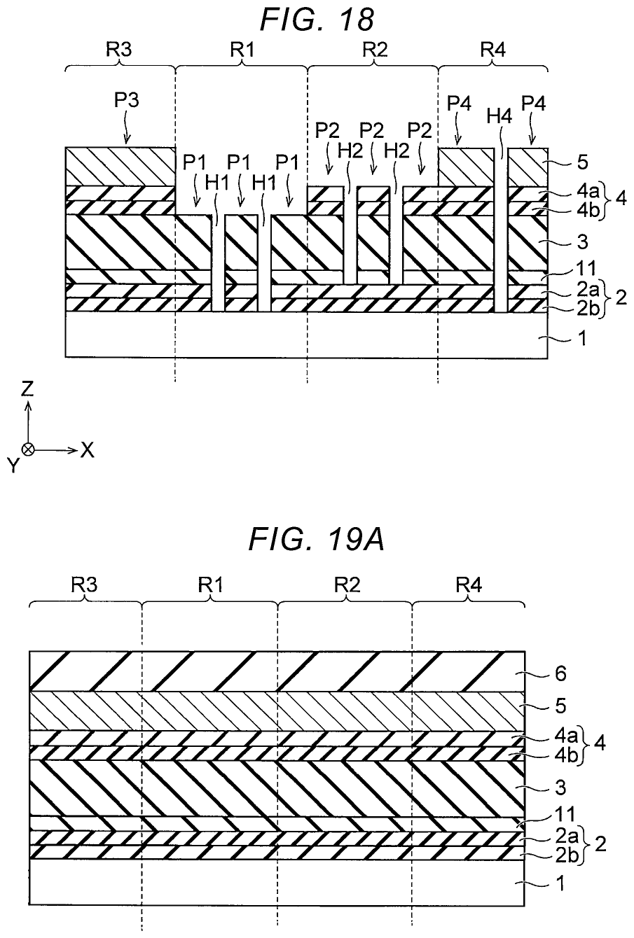

FIG. 18 is a cross-sectional view showing a structure of a photomask according to a third embodiment.

The photomask according to the present embodiment has the same structure as the photomask according to the second embodiment. Meanwhile, a transmittance adjusting film 2 according to the present embodiment includes a transmittance adjusting film 2b formed on a substrate 1 and a transmittance adjusting film 2a formed on the transmittance adjusting film 2b. In the present embodiment, the transmittance adjusting film 2b is an example of a first film, and the transmittance adjusting film 2a is an example of a second film. Further, the photomask according to the present embodiment includes an etching stopper film 11.

The etching stopper film 11 is formed between the transmittance adjusting film 2 and an HT film 3. Therefore, the HT film 3 according to the present embodiment is formed on the transmittance adjusting film 2 via the etching stopper film 11. The etching stopper film 11 according to the present embodiment has a film thickness smaller than the film thickness of the HT film 3. The etching stopper film 11 is, for example, an HfOₓ film. The etching stopper film 11 may be a film other than the HfOₓ film, and for example, may be an Hf film or an HEN film, a single metal film containing Cr, Al, W, Ta, Mo, Y, or Ru, a metal oxide film, or a metal nitride film.

The etching stopper film 11 functions as an etching stopper when forming the recess portions H1, H2, and H4 in the HT film 3 by RIE. Therefore, an etching selectivity of the etching stopper film 11 with respect to the HT film 3 is set to a low value (for example, 1/10 or less). For example, by using the HT film 3 as the SiN film and the etching stopper film 11 as the HfOₓ film, it is possible to achieve such an etching selectivity.

When the etching stopper film 11 is not present, there is a concern that the recess portion H2 is also formed in the transmittance adjusting film 2 when the recess portion H2 is formed in the HT film 3. This is referred to as a film loss of the transmittance adjusting film 2. When the depth of the recess portion H2 in the transmittance adjusting film 2 increases, there is a concern that the optical characteristics of the region R2 may be different from the designed characteristics. On the other hand, according to the present embodiment, by forming the etching stopper film 11 between the transmittance adjusting film 2 and the HT film 3, it is possible to prevent the film loss of the transmittance adjusting film 2.

In addition, the regions R1 to R4 according to the present embodiment have the same characteristics as the regions R1 to R4 of the first embodiment. For example, in the transmittance adjusting film 2, the etching stopper film 11, and the HT film 3 according to the present embodiment, the a phase of the ArF light transmitted through transmittance adjusting film 2, the etching stopper film 11, and the HT film 3 is different from a phase of the ArF light passed through the atmosphere by substantially 180 degrees. In addition, in the etching stopper film 11, the HT film 3, and the transmittance adjusting film 4 of the present embodiment, a phase of the ArF light transmitted through the etching stopper film 11, the HT film 3, and the transmittance adjusting film 4 is different from a phase of the ArF light passed through the atmosphere by substantially 180 degrees. Therefore, with the photomask according to the present embodiment, it is possible to obtain the same effects as those of the photomasks of the first and second embodiments.

### 2) Manufacturing Method of Photomask According to Third Embodiment

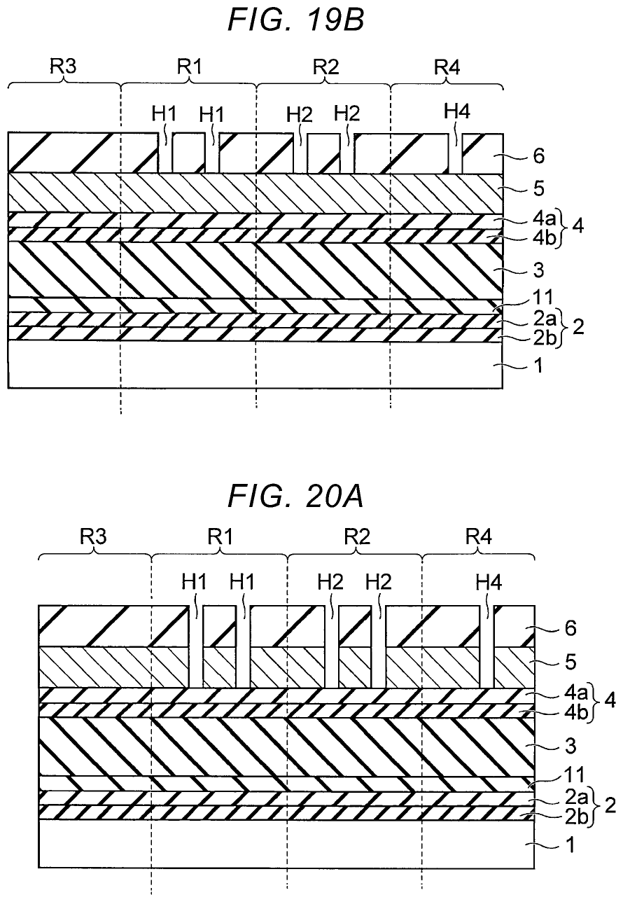

FIGS. 19A to 26B are cross-sectional views showing a manufacturing method of the photomask according to the third embodiment.

First, a substrate 1 is prepared, and a transmittance adjusting film 2, an etching stopper film 11, an HT film 3, a transmittance adjusting film 4, a light shielding film 5, and a resist film 6 are sequentially formed on the substrate 1 (FIG. 19A). As a result, a photomask blank including the substrate 1, the transmittance adjusting film 2, the etching stopper film 11, the HT film 3, the transmittance adjusting film 4, the light shielding film 5, and the resist film 6 is manufactured. FIG. 19A shows regions R1 to R4 in the same manner as in FIG. 18. The transmittance adjusting film 2 is formed by sequentially forming transmittance adjusting films 2b and 2a on the substrate 1. The transmittance adjusting film 4 is formed by sequentially forming transmittance adjusting films 4b and 4a on the HT film 3.

Next, recess portions H1, H2, and H4 are formed in the resist film 6 of the regions R1, R2, and R4 by EB drawing and development, respectively (FIG. 19B).

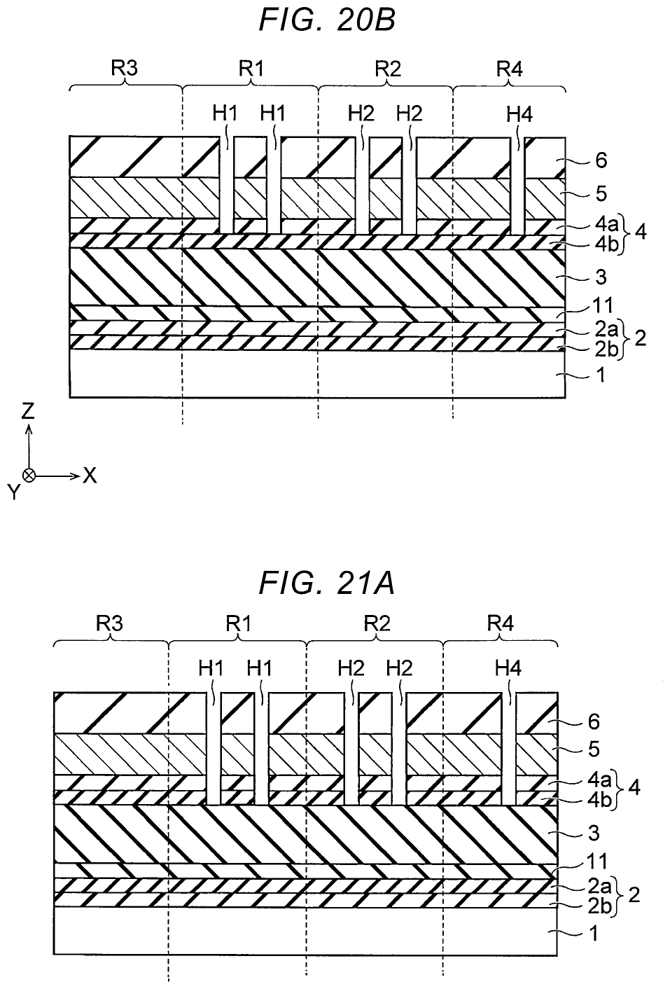

Next, the light shielding film 5 is processed by RIE using the resist film 6 (FIG. 20A). As a result, the recess portions H1, H2, and H4 are also formed in the light shielding film 5.

Next, the transmittance adjusting film 4a is processed by RIE using the resist film 6 (FIG. 20B). As a result, the recess portions H1, H2, and H4 are also formed in the transmittance adjusting film 4a.

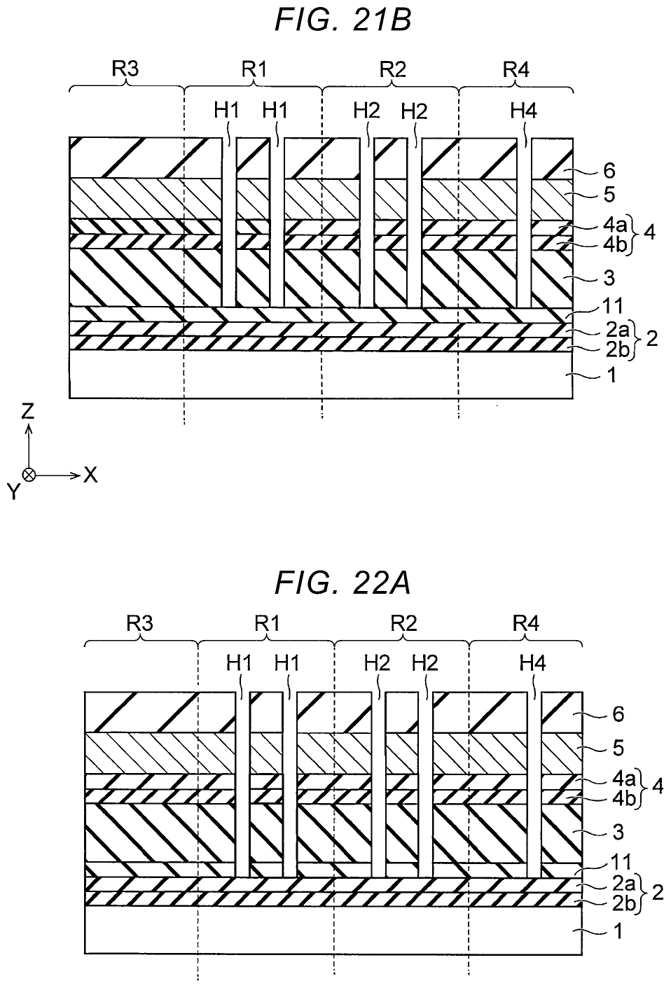

Next, the transmittance adjusting film 4b is processed by RIE using the resist film 6 (FIG. 21A). As a result, the recess portions H1, H2, and H4 are also formed in the transmittance adjusting film 4b.

Next, the HT film 3 is processed by the RIE using the resist film 6 (FIG. 21B). As a result, the recess portions H1, H2, and H4 are also formed in the HT film 3. In this case, the etching stopper film 11 functions as an etching stopper which stops the progress of RIE.

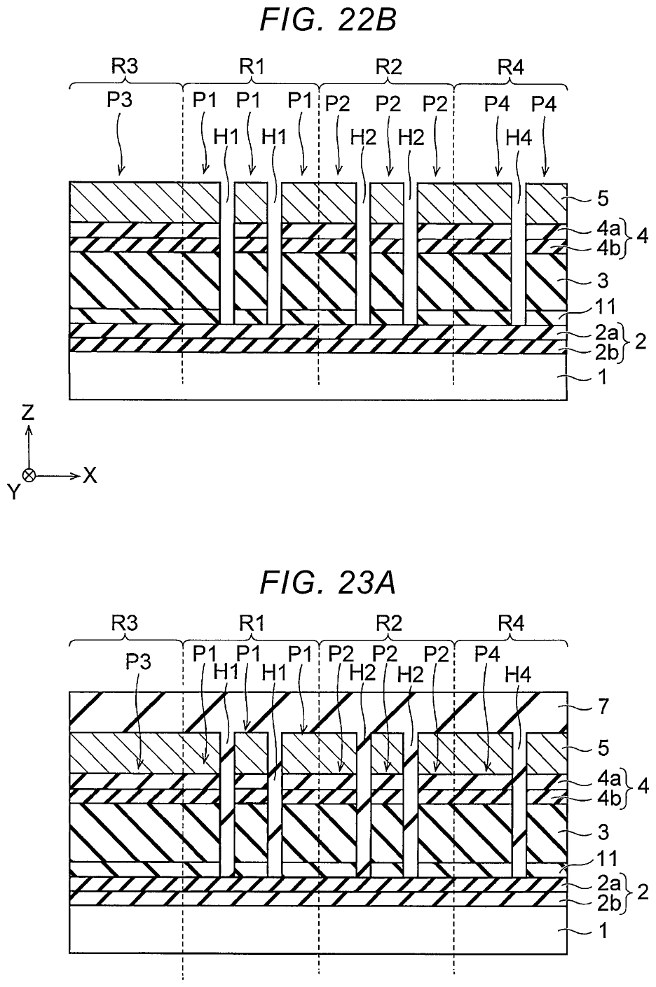

Next, the etching stopper film 11 is processed by RIE using the resist film 6 (FIG. 22A). As a result, the recess portions H1, H2, and H4 are also formed in the etching stopper film 11. The RIE in the step of FIG. 22A is performed using, for example, BCl₃ gas.

Next, the resist film 6 is peeled off (FIG. 22B). In this way, pattern portions P1, P2, P3, and P4 are formed in the regions R1, R2, R3, and R4, respectively.

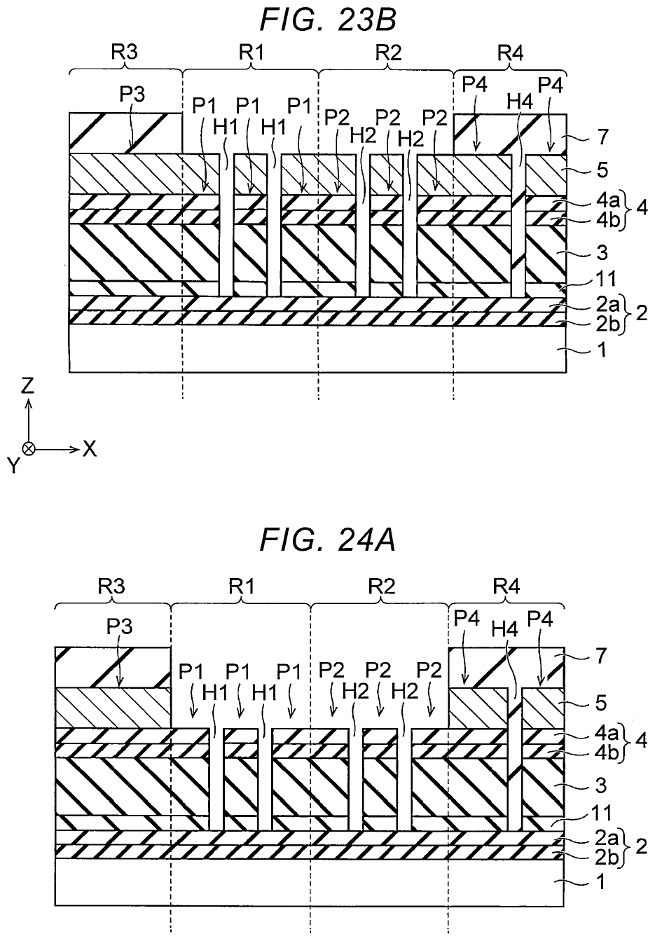

Next, a resist film 7 is formed on the light shielding film 5 (FIG. 23A). The resist film 7 is also formed in the recess portions H1, H2, and H4. Next, the resist film 7 is removed from the regions R1 and R2 by laser drawing and development (FIG. 23B).

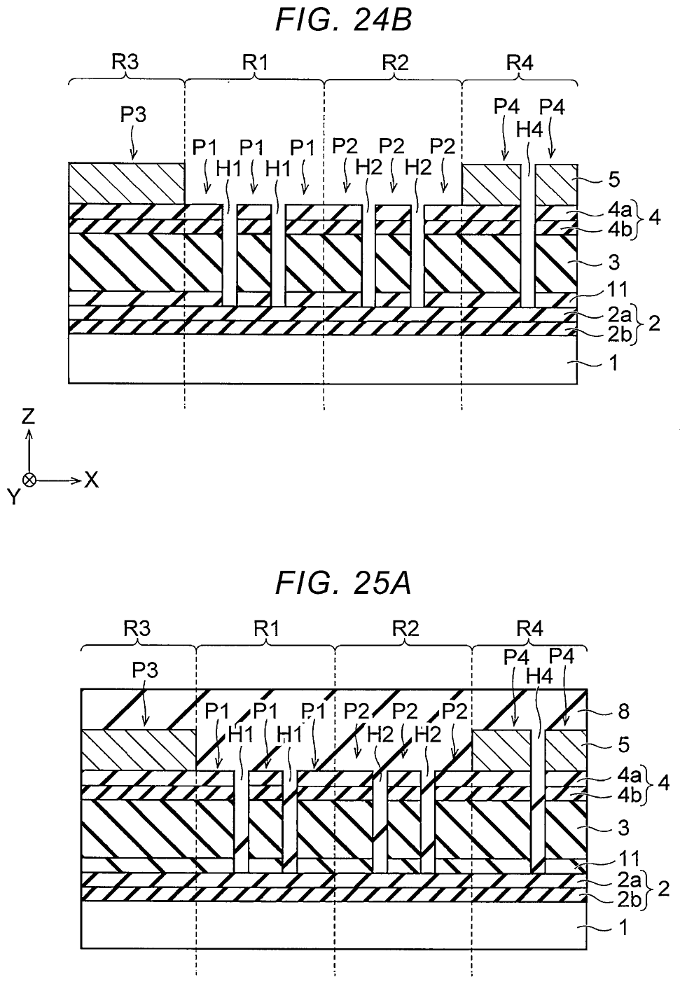

Next, the light shielding film 5 is processed by RIE using the resist film 7 (FIG. 24A). As a result, the light shielding film 5 is removed from the regions R1 and R2. Next, the resist film 7 is peeled off (FIG. 24B).

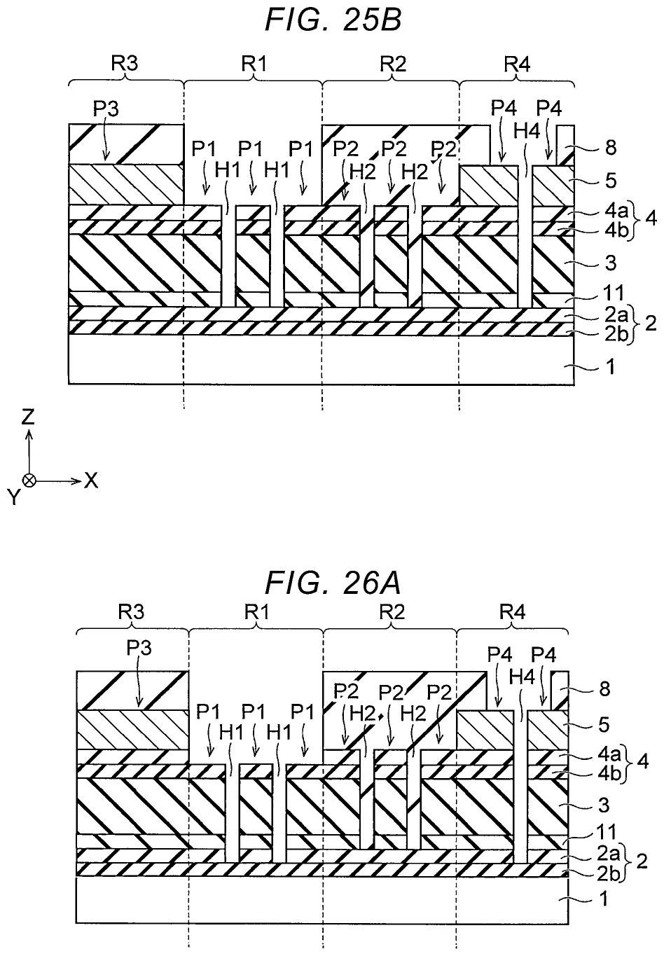

Next, a resist film 8 is formed on the light shielding film 5 and the transmittance adjusting film 4 (FIG. 25A). The resist film 8 is also formed in the recess portions H1, H2, and H4. Next, the resist film 8 is removed from the entire region R1 and a part of the region R4 by laser drawing and development (FIG. 25B).

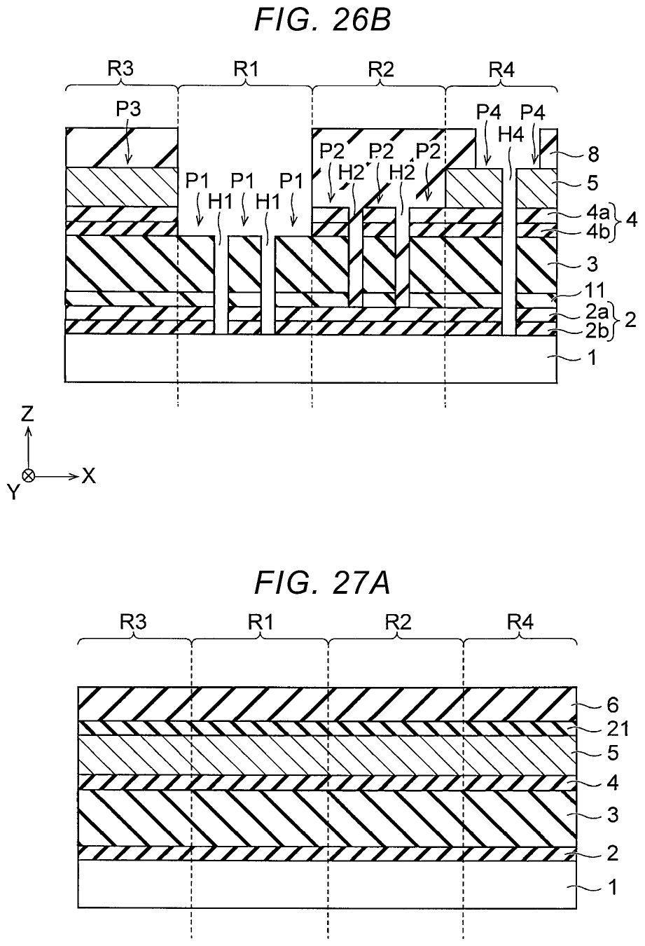

Next, the transmittance adjusting films 2a and 4a are simultaneously processed by RIE using the resist film 8 (FIG. 26A). As a result, the recess portions H1 and H4 are also formed in the transmittance adjusting film 2a, and the transmittance adjusting film 4a is removed from the region R1. The RIE in the step of FIG. 26A is performed using, for example, SF₆ gas and Ar gas.

Next, the transmittance adjusting films 2b and 4b are simultaneously processed by RIE using the resist films 8 (FIG. 26B). As a result, the recess portions H1 and H4 are also formed in the transmittance adjusting film 2b, and the transmittance adjusting film 4b is removed from the region R1. The RIE in the step of FIG. 26B is performed using, for example, BCl₃ gas. Thereafter, the resist film 8 is peeled off.

In this way, the photomask shown in FIG. 18 is manufactured.

As described above, the photomask pattern according to the present embodiment is formed of the transmittance adjusting film 2, the etching stopper film 11, and the HT film 3 in the region R1, and is formed of the etching stopper film 11, the HT film 3, and the transmittance adjusting film 4 in the region R2. As a result, there is a difference that the transmittance adjusting film 2 is formed on the lower side of the HT film 3, and the transmittance adjusting film 4 is formed on the upper side of the HT film 3, but both the pattern portion P1 of the region R1 and the pattern portion P2 of the region R2 include the HT film and the transmittance adjusting film. Therefore, according to the present embodiment, it is possible to reduce the region dependence of the transmittance of light in the film forming the photomask pattern. Further, according to the present embodiment, by forming the etching stopper film 11 between the transmittance adjusting film 2 and the HT film 3, it is possible to prevent the film loss of the transmittance adjusting film 2.

### Fourth Embodiment

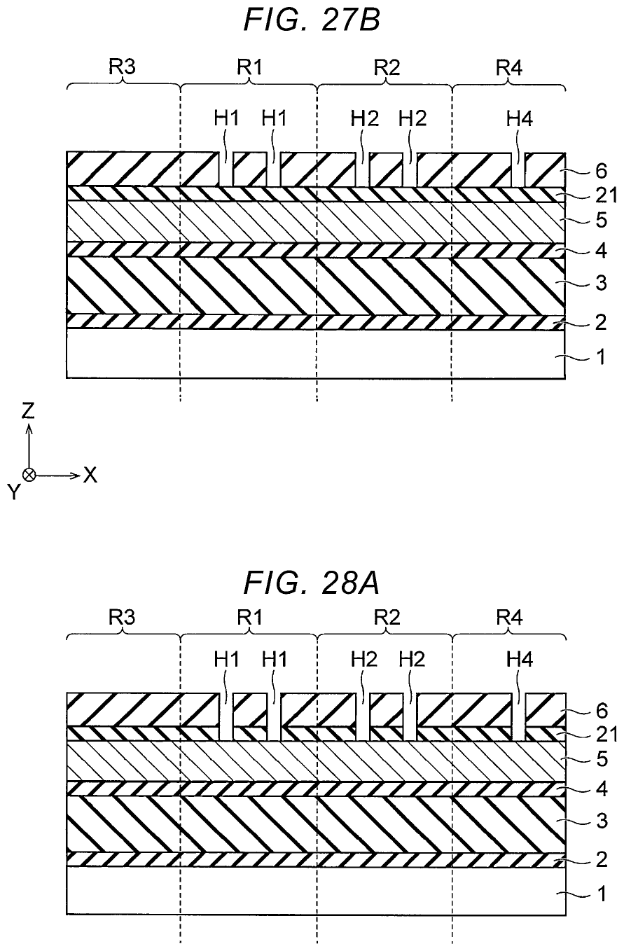

FIGS. 27A to 33B are cross-sectional views showing a manufacturing method of a photomask according to a fourth embodiment. In the present embodiment, the photomask having the structure shown in FIG. 1 (first embodiment) is manufactured by using a hard mask film 21. The hard mask film 21 is, for example, an SiO₂ film.

First, a substrate 1 is prepared, and a transmittance adjusting film 2, an HT film 3, a transmittance adjusting film 4, a light shielding film 5, a hard mask film 21, and a resist film 6 are sequentially formed on the substrate 1 (FIG. 27A). As a result, a photomask blank including the substrate 1, the transmittance adjusting film 2, the HT film 3, the transmittance adjusting film 4, the light shielding film 5, the hard mask film 21, and the resist film 6 is manufactured. FIG. 27A shows regions R1 to R4 in the same manner as in FIG. 1.

Next, recess portions H1, H2, and H4 are formed in the resist film 6 in the regions R1, R2, and R4 by EB drawing and the development, respectively (FIG. 27B).

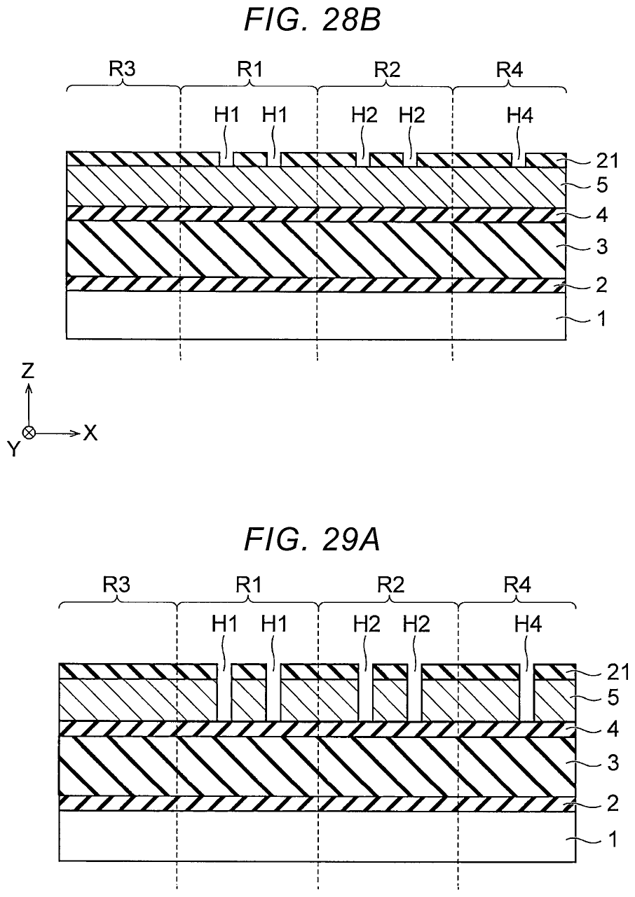

Next, the hard mask film 21 is processed by RIE using the resist film 6 (FIG. 28A). As a result, the pattern of the resist film 6 is transferred to the hard mask film 21, and the recess portions H1, H2, and H4 are also formed in the hard mask film 21. The RIE in the step of FIG. 28A is performed using, for example, SF₆ gas and Ar gas. Next, the resist film 6 is peeled off (FIG. 28B).

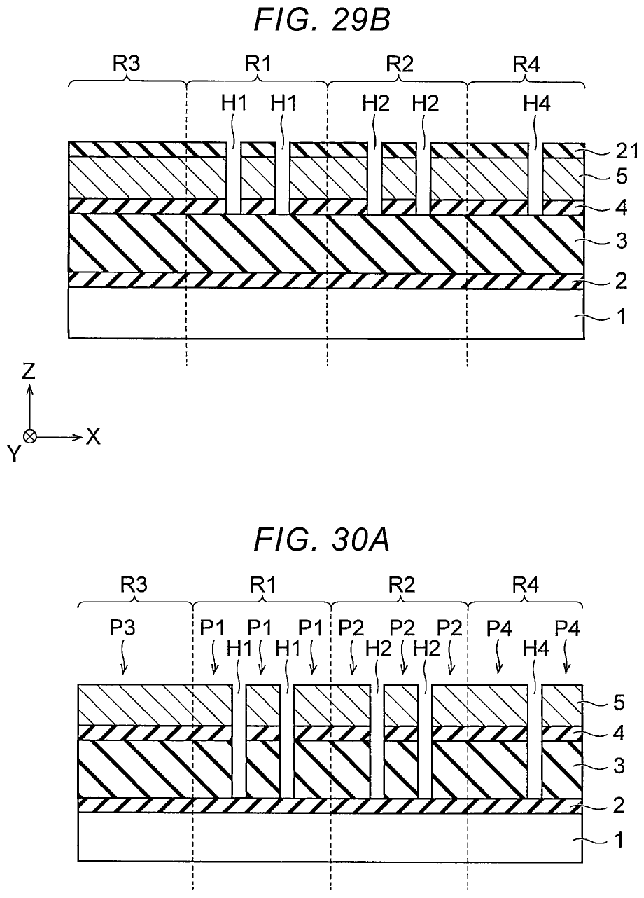

Next, the light shielding film 5 is processed by RIE using the hard mask film 21 (FIG. 29A). As a result, the pattern of the hard mask film 21 is transferred to the light shielding film 5, and the recess portions H1, H2, and H4 are also formed in the light shielding film 5.

Next, the transmittance adjusting film 4 is processed by RIE using the hard mask film 21 (FIG. 29B). As a result, the pattern of the hard mask film 21 is transferred to the transmittance adjusting film 4, and the recess portions H1, H2, and H4 are also formed in the transmittance adjusting film 4.

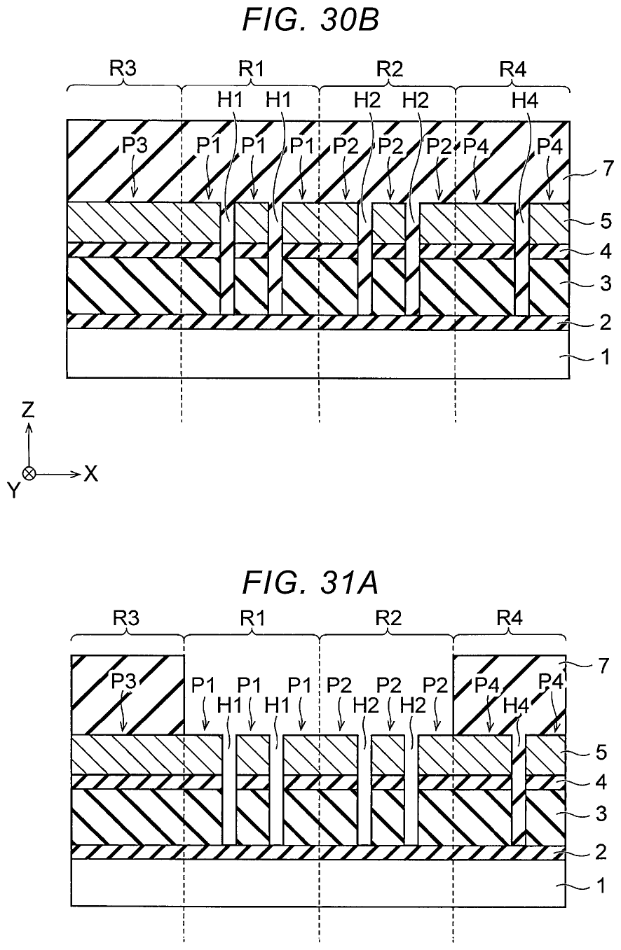

Next, the HT film 3 is processed by RIE using the hard mask film 21 (FIG. 30A). As a result, the pattern of the hard mask film 21 is transferred to the HT film 3, and the recess portions H1, H2, and H4 are also formed in the HT film 3. In the step shown in FIG. 30A, the hard mask film 21 is also removed. In this way, pattern portions P1, P2, P3, and P4 are formed in the regions R1, R2, R3, and R4, respectively.

Next, a resist film 7 is formed on the light shielding film 5 (FIG. 30B). The resist film 7 is also formed in the recess portions H1, H2, and H4.

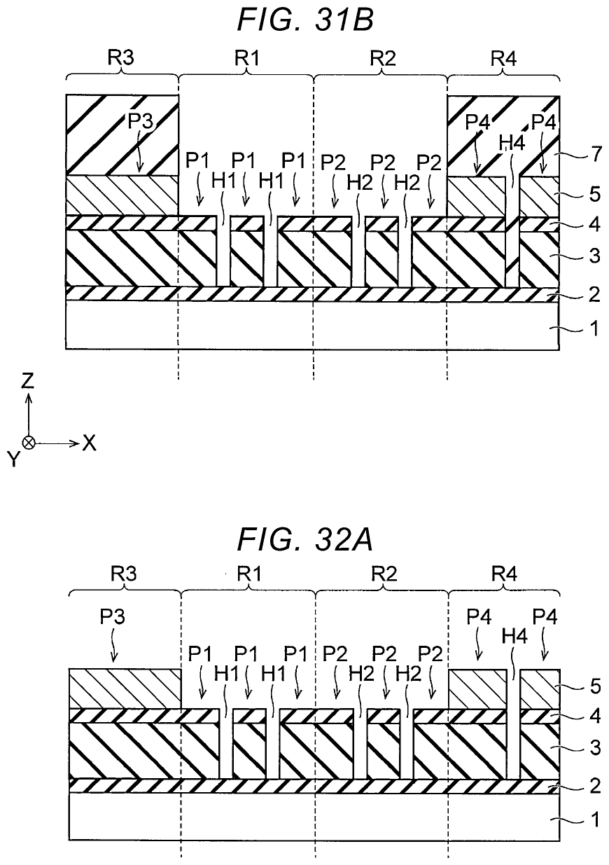

Next, the resist film 7 is removed from the regions R1 and R2 by laser drawing and development (FIG. 31A). Next, the light shielding film 5 is processed by RIE using the resist film 7 (FIG. 31B). As a result, the light shielding film 5 is removed from the regions R1 and R2.

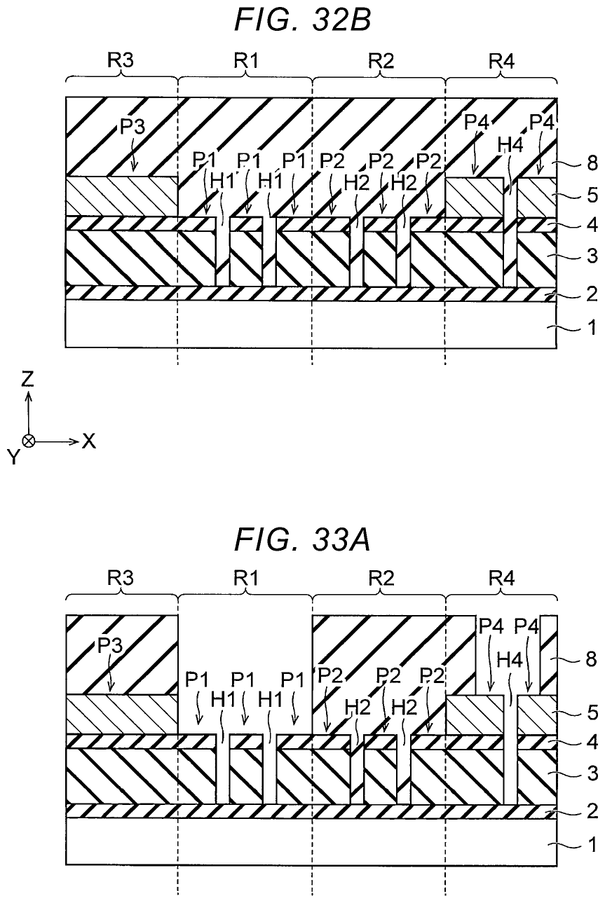

Next, the resist film 7 is peeled off (FIG. 32A). Next, a resist film 8 is formed on the light shielding film 5 and the transmittance adjusting film 4 (FIG. 32B). The resist film 8 is also formed in the recess portions H1, H2, and H4.

Next, the resist film 8 is removed from the entire region R1 and a part of the region R4 by laser drawing and development (FIG. 32A). Next, the transmittance adjusting films 2 and 4 are simultaneously processed by RIE using the resist film 8 (FIG. 32B). As a result, the recess portions H1 and H4 are also formed in the transmittance adjusting film 2, and the transmittance adjusting film 4 is removed from the region R1. Thereafter, the resist film 8 is peeled off.

In this way, the photomask shown in FIG. 1 is manufactured.

As described above, the photomask pattern according to the present embodiment is formed of the transmittance adjusting film 2 and the HT film 3 in the region R1, and is formed of the HT film 3 and the transmittance adjusting film 4 in the region R2. As a result, there is a difference that the transmittance adjusting film 2 is formed on the lower side of the HT film 3, and the transmittance adjusting film 4 is formed on the upper side of the HT film 3, but both the pattern portion P1 of the region R1 and the pattern portion P2 of the region R2 include the HT film and the transmittance adjusting film. Therefore, according to the present embodiment, it is possible to reduce the region dependence of the transmittance of light in the film forming the photomask pattern.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A photomask blank comprising:
a substrate;
a first transmittance adjusting film provided on the substrate;
a phase shifter film provided on the first transmittance adjusting film; and
a second transmittance adjusting film provided on the phase shifter film,
wherein, when light having a wavelength is transmitted through the phase shifter film,
(i) a phase of the light transmitted through the phase shifter film and the first transmittance adjusting film is different from a phase of light passed through atmosphere by about 180 degrees, and
(ii) a phase of the light transmitted through the phase shifter film and the second transmittance adjusting film is different from the phase of the light passed through the atmosphere by about 180 degrees.

2. The photomask blank according to claim 1, wherein the light includes ArF excimer laser light.

3. The photomask blank according to claim 1, wherein a film thickness of the first transmittance adjusting film and a film thickness of the second transmittance adjusting film are each less than a film thickness of the phase shifter film.

4. The photomask blank according to claim 1, wherein the phase shifter film includes silicon (Si) and nitrogen (N).

5. The photomask blank according to claim 1, wherein at least one of the first transmittance adjusting film or the second transmittance adjusting film includes hafnium (Hf), chromium (Cr), aluminum (Al), tungsten (W), tantalum (Ta), molybdenum (Mo), yttrium (Y), or ruthenium (Ru).

6. The photomask blank according to claim 1, wherein at least one of the first transmittance adjusting film or the second transmittance adjusting film includes a first film and a second film.

7. The photomask blank according to claim 6,
wherein one of the first film or the second film includes silicon (Si) and nitrogen (N), and
the other of the first film or the second film includes hafnium (Hf), chromium (Cr), aluminum (Al), tungsten (W), tantalum (Ta), molybdenum (Mo), yttrium (Y), or ruthenium (Ru).

8. The photomask blank according to claim 1, further comprising an etching stopper film provided between the first transmittance adjusting film and the phase shifter film.

9. The photomask blank according to claim 8, wherein a film thickness of the etching stopper film is less than a film thickness of the phase shifter film.

10. The photomask blank according to claim 8, wherein the etching stopper film includes hafnium (Hf), chromium (Cr), aluminum (Al), tungsten (W), tantalum (Ta), molybdenum (Mo), yttrium (Y), or ruthenium (Ru).

11. A photomask comprising:
a first region including a substrate, a first transmittance adjusting film provided on the substrate, and a phase shifter film provided on the first transmittance adjusting film, the first region having a first recess penetrating the phase shifter film and the first transmittance adjusting film to the substrate; and
a second region including the substrate, the first transmittance adjusting film, the phase shifter film, and a second transmittance adjusting film provided on the phase shifter film, the second region having a second recess penetrating the second transmittance adjusting film and the phase shifter film to the first transmittance adjusting film.

12. The photomask according to claim 11, further comprising a third region including the substrate, the first transmittance adjusting film, the phase shifter film, the second transmittance adjusting film, and a light shielding film provided on the second transmittance adjusting film.

13. The photomask according to claim 11, wherein at least one of the first transmittance adjusting film or the second transmittance adjusting film includes a first film and a second film.

14. The photomask according to claim 11, wherein the first region and the second region further include an etching stopper film provided between the first transmittance adjusting film and the phase shifter film.

15. A manufacturing method of a photomask comprising:
forming a first region including a substrate, a first transmittance adjusting film provided on the substrate, and a phase shifter film provided on the first transmittance adjusting film;
forming a first recess in the first region, the first recess penetrating the phase shifter film and the first transmittance adjusting film to the substrate;
forming a second region including the substrate, the first transmittance adjusting film, the phase shifter film, and a second transmittance adjusting film provided on the phase shifter film; and
forming a second recess in the second region, the second recess portion penetrating the second transmittance adjusting film and the phase shifter film to the first transmittance adjusting film.

16. The manufacturing method of a photomask according to claim 15, further comprising forming a third region including the substrate, the first transmittance adjusting film, the phase shifter film, the second transmittance adjusting film, and a light shielding film provided on the second transmittance adjusting film.

17. The manufacturing method of a photomask according to claim 16, further comprising:
removing the light shielding film and the second transmittance adjusting film from the first region; and
removing the light shielding film from the second region,
wherein the first region, the second region, and the third region include the substrate, the first transmittance adjusting film, the phase shifter film, the second transmittance adjusting film, and the light shielding film.

18. The manufacturing method of a photomask according to claim 17,
wherein the second recess portion is formed in the second transmittance adjusting film and the phase shifter film before removing the light shielding film from the second region, and
the first recess portion is formed in the second transmittance adjusting film and the phase shifter film before removing the light shielding film from the first region, and is formed in the first transmittance adjusting film during or before removing the second transmittance adjusting film from the first region.

19. The manufacturing method of a photomask according to claim 15, wherein at least one of the first transmittance adjusting film or the second transmittance adjusting film includes a first film and a second film.

20. The manufacturing method of a photomask according to claim 15, wherein the phase shifter film is formed on the first transmittance adjusting film via an etching stopper film.
